(19) United States
(12) Patent Application Publication
(10) Pub. No.: US 2026/0333722 A1
(43) Pub. Date: Oct. 22, 2026

(54) SEMICONDUCTOR DEVICE, MODULE UNIT, AND METHOD FOR MANUFACTURING SEMICONDUCTOR DEVICE

(71) Applicant: Murata Manufacturing Co., Ltd., Kyoto-fu (JP)

(72) Inventors: Yoshimasa YOSHIOKA, Nagaokakyo-shi (JP); Hiroshi NAKAGAWA, Nagaokakyo-shi (JP)

(73) Assignee: Murata Manufacturing Co., Ltd., Kyoto-fu (JP)

(21) Appl. No.: 19/687,464

(22) Filed: May 26, 2026

Related U.S. Application Data
(63) Continuation of application No. PCT/JP2024/019391, filed on May 27, 2024.

(30) Foreign Application Priority Data
Nov. 28, 2023 (JP) 2023-200785

(51) Int. Cl. H10D 1/68; H10D 1/00; H10D 80/30; H10W 42/20; H10W 44/00; H10W 70/00; H10W 70/05; H10W 70/65; H10W 90/00

(52) U.S. Cl. CPC H10D 1/716; H10D 1/041; H10W 44/601; H10W 70/099; H10W 70/6565; H10D 80/30; H10W 42/287; H10W 90/7295; H10W 90/794

(57) ABSTRACT

A semiconductor device that can increase capacitance of a capacitor portion. A semiconductor device includes a semiconductor substrate including one main surface and the other main surface that is provided while being spaced away from the one main surface along a thickness direction and faces in a direction opposite to the one main surface along the thickness direction, at least one first trench in the one main surface, and at least one second trench in the other main surface; a first capacitor portion that is provided at least in the first trench and includes a dielectric layer and two electrode layers between which the dielectric layer is sandwiched; and a second capacitor portion that is provided at least in the second trench and includes a dielectric layer and two electrode layers between which the dielectric layer is sandwiched.

### CROSS-REFERENCE TO RELATED APPLICATIONS

This application claims benefit of priority to International Patent Application No. PCT/JP2024/019391, filed May 27, 2024, and to Japanese Patent Application No. 2023-200785, filed Nov. 28, 2023, the entire contents of each are incorporated herein by reference.

### BACKGROUND

### Technical Field

The present disclosure relates to a semiconductor device in which a capacitor portion is provided in a trench.

### Background Art

As one example of a semiconductor device in which a capacitor portion is provided in a trench, there is disclosed a capacitor that includes a substrate having a recess in a surface thereof, and includes a dielectric film and a conductor film that are provided in the recess.

### SUMMARY

The semiconductor device in which the capacitor portion is provided in the trench is still susceptible to improvement from the viewpoint of increasing the capacitance of the capacitor portion.

Therefore, the present disclosure provides a semiconductor device, a module unit, and a method for manufacturing a semiconductor device that can increase the capacitance of the capacitor portion.

That is, a semiconductor device according to the present disclosure includes a semiconductor substrate including one main surface and the other main surface that is provided while being spaced away from the one main surface along a thickness direction and faces in a direction opposite to the one main surface along the thickness direction, the semiconductor substrate including at least one first trench in the one main surface and at least one second trench in the other main surface; a first capacitor portion that is provided at least in the first trench and includes a dielectric layer and two electrode layers between which the dielectric layer is sandwiched; and a second capacitor portion that is provided at least in the second trench and includes a dielectric layer and two electrode layers between which the dielectric layer is sandwiched.

Further, a module unit according to the present disclosure includes the semiconductor device; an electronic component; and a mounting board in which the semiconductor device is provided, the mounting board including a mounting surface on which the electronic component is mounted.

Further, a method for manufacturing a semiconductor device according to the present disclosure includes a first-trench forming step of forming at least one first trench in a main surface of a first substrate; a first-capacitor-portion forming step of forming a first capacitor portion including a dielectric layer and two electrode layers between which the dielectric layer is sandwiched, in at least the first trench in the first substrate; a second-trench forming step of forming at least one second trench in a main surface of a second substrate; a second-capacitor-portion forming step of forming a second capacitor portion including a dielectric layer and two electrode layers between which the dielectric layer is sandwiched, in at least the second trench in the second substrate; and a bonding step of bonding a rear surface with respect to the main surface of the first substrate and a rear surface with respect to the main surface of the second substrate.

According to the present disclosure, it is possible to provide a semiconductor device, a module unit, and a method for manufacturing a semiconductor device that can increase the capacitance of the capacitor portion.

### BRIEF DESCRIPTION OF THE DRAWINGS

FIG. 1 is a plan view of a semiconductor device according to an embodiment of the present disclosure;

FIG. 2 is a schematic sectional view for illustrating a section taken along the line II-II in FIG. 1;

FIG. 3 is an equivalent circuit diagram of the semiconductor device according to the embodiment of the present disclosure;

FIG. 4 is a schematic sectional view for illustrating a method for manufacturing the semiconductor device according to the embodiment of the present disclosure;

FIG. 5 is a schematic sectional view for illustrating the method for manufacturing the semiconductor device according to the embodiment of the present disclosure;

FIG. 6 is a schematic sectional view for illustrating the method for manufacturing the semiconductor device according to the embodiment of the present disclosure;

FIG. 7 is a schematic sectional view for illustrating the method for manufacturing the semiconductor device according to the embodiment of the present disclosure;

FIG. 8 is a schematic sectional view for illustrating the method for manufacturing the semiconductor device according to the embodiment of the present disclosure;

FIG. 9 is a schematic sectional view for illustrating the method for manufacturing the semiconductor device according to the embodiment of the present disclosure;

FIG. 10 is a schematic sectional view for illustrating the method for manufacturing the semiconductor device according to the embodiment of the present disclosure;

FIG. 11 is a schematic sectional view for illustrating the method for manufacturing the semiconductor device according to the embodiment of the present disclosure;

FIG. 12 is a schematic sectional view of a modification of the semiconductor device according to the embodiment of the present disclosure;

FIG. 13 is an equivalent circuit diagram of the semiconductor device illustrated in FIG. 12;

FIG. 14 is a schematic sectional view of a modification of the semiconductor device according to the embodiment of the present disclosure;

FIG. 15 is a schematic sectional view of a modification of the semiconductor device according to the embodiment of the present disclosure;

FIG. 16 is an equivalent circuit diagram of the semiconductor device illustrated in FIG. 15;

FIG. 17 is a schematic sectional view of a modification of the semiconductor device according to the embodiment of the present disclosure;

FIG. 18 is a schematic sectional view of a modification of the semiconductor device according to the embodiment of the present disclosure;

FIG. 19 is a schematic sectional view of a modification of the semiconductor device according to the embodiment of the present disclosure; and

FIG. 20 is a schematic sectional view of a module unit according to the embodiment of the present disclosure.

### DETAILED DESCRIPTION

An example of the present disclosure is described below with reference to the accompanying drawings. Note that the following description is a mere example in nature, and is not intended to limit the present disclosure, its application, or its use. Further, the drawings are schematic, and ratios and the like of the dimensions are not necessarily identical to those in actual cases. Moreover, in the following description, terms (for example, terms including “upper”, “lower”, “right”, “left”, “front”, and “rear”) representing specific directions or positions are used as needed. However, the terms representing specific directions or positions are used for the purpose of facilitating understanding of the present disclosure with reference to the drawings, and the technical scope of the present disclosure is not limited by the meanings of those terms.

### Semiconductor Device

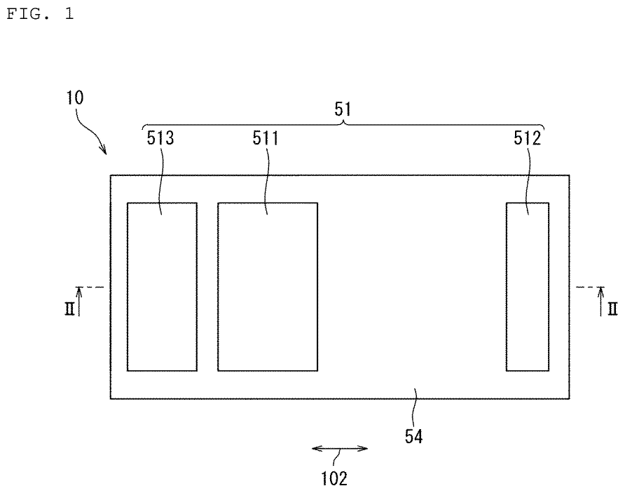

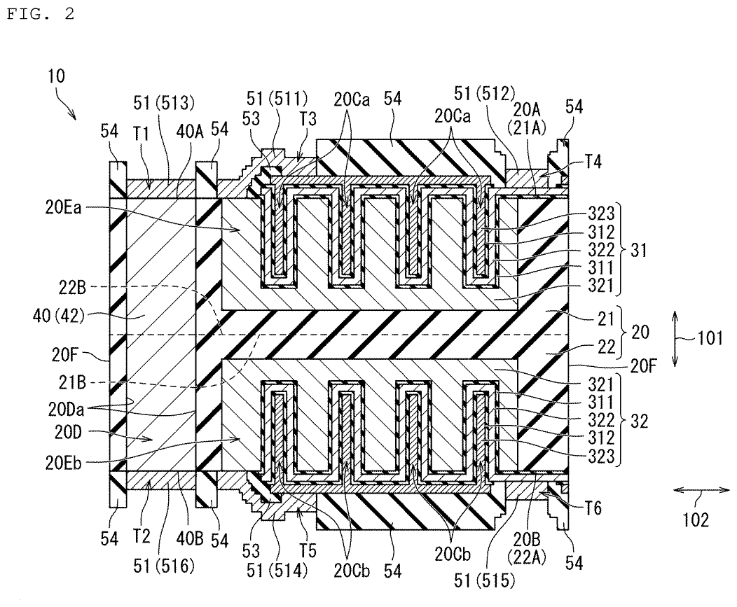

FIG. 1 is a plan view of a semiconductor device according to an embodiment of the present disclosure. FIG. 2 is a schematic sectional view for illustrating a section taken along the line II-II in FIG. 1.

As illustrated in FIG. 1 and FIG. 2, the semiconductor device 10 includes a semiconductor substrate 20, a first capacitor portion 31, a second capacitor portion 32, a filling portion 40, a first insulating layer 53, a second insulating layer 54, and external terminals 51.

The semiconductor substrate 20 is, for example, a silicon (Si) substrate, and includes high-resistance Si having an insulation property.

The semiconductor substrate 20 includes one main surface 20A, the other main surface 20B, and a side surface 20F. The one main surface 20A and the other main surface 20B are provided while being spaced away from each other along a thickness direction 101 of the semiconductor substrate 20. The one main surface 20A and the other main surface 20B face in directions opposite to each other along the thickness direction 101. The side surface 20F connects an outer edge of the one main surface 20A and an outer edge of the other main surface 20B.

The semiconductor substrate 20 includes recesses 20Ea and 20Eb, four first trenches 20Ca, and four second trenches 20Cb.

The recess 20Ea is filled with a first electrode layer 321 of the first capacitor portion 31 described later. The first electrode layer 321 of the first capacitor portion 31 forms a part of the one main surface 20A of the semiconductor substrate 20. The recess 20Eb is filled with a first electrode layer 321 of a second capacitor portion 32 described later. The first electrode layer 321 of the second capacitor portion 32 forms a part of the other main surface 20B of the semiconductor substrate 20. In the present embodiment, the first electrode layer 321 of the first capacitor portion 31 is a part of the first capacitor portion 31 and is also a part of the semiconductor substrate 20. Further, in the present embodiment, a second electrode layer of the second capacitor portion 32 is a part of the second capacitor portion 32 and is also a part of the semiconductor substrate 20.

In FIG. 2, the recess 20Ea is provided in the one main surface 20A, and the recess 20Eb is provided in the other main surface 20B. That is, the semiconductor substrate 20 includes two recesses. However, the number of recesses included in the semiconductor substrate 20 is not limited to two. For example, a plurality of recesses 20Ea may be provided in the one main surface 20A. Alternatively, for example, a plurality of recesses 20Eb may be provided in the other main surface 20B.

The four first trenches 20Ca are each provided in a portion forming a part of the one main surface 20A in the first electrode layer 321 and are recessed in the thickness direction 101. That is, each of the four first trenches 20Ca is a recess provided in the one main surface 20A. The four second trenches 20Cb are each provided in a portion forming a part of the other main surface 20B in the first electrode layer 321 and are recessed in the thickness direction 101. That is, each of the four second trenches 20Cb is a recess provided in the other main surface 20B.

The first trench 20Ca and the second trench 20Cb can have any shape. For example, the first trench 20Ca and the second trench 20Cb may each have a shape of a circle or a shape of a rectangle as viewed along the thickness direction 101, or may each be a narrow groove extending sinuously or straightly. The groove may be divided into a plurality of branches. The four first trenches 20Ca may have the same shape or different shapes. The four second trenches 20Cb may have the same shape or different shapes. The first trench 20Ca and the second trench 20Cb may have the same shape or different shapes.

FIG. 2 illustrates the four first trenches 20Ca and the four second trenches 20Cb, but the number of the first trenches 20Ca included in the semiconductor substrate 20 is not limited to four, and the number of the second trenches 20Cb included in the semiconductor substrate 20 is not limited to four. The semiconductor substrate 20 is only required to include at least one first trench 20Ca and at least one second trench 20Cb.

The semiconductor substrate 20 includes a hole 20D. The hole 20D is drilled through the semiconductor substrate 20 along the thickness direction 101. The hole 20D extends along the thickness direction 101 and opens to both the one main surface 20A and the other main surface 20B. The hole 20D has a side surface 20Da. In the present embodiment, the hole 20D has a shape of a circle as viewed along the thickness direction 101. That is, the hole 20D has a tubular shape.

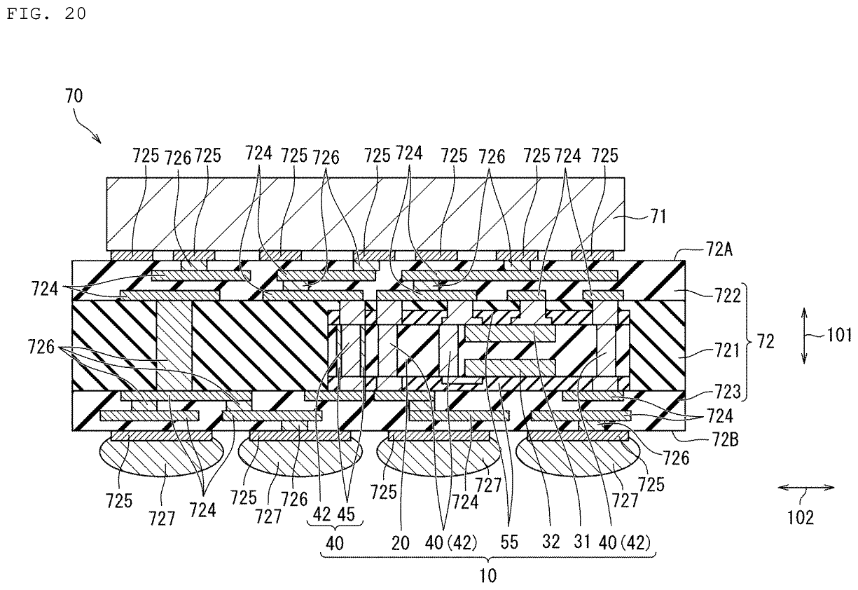

The hole 20D is not necessarily required to be drilled through the semiconductor substrate 20 along the thickness direction 101. That is, the hole 20D may open to only one of the one main surface 20A and the other main surface 20B. For example, the hole 20D may be configured so as not to open to the other main surface 20B while opening to the one main surface 20A as in a modification described later with reference to FIG. 19. Alternatively, for example, the hole 20D may be configured so as not to open to the one main surface 20A while opening to the other main surface 20B.

The hole 20D, like the first trench 20Ca and the second trench 20Cb, can have any shape. For example, the hole 20D may have a shape of a circle or a shape of a rectangle as viewed along the thickness direction 101, or may be a narrow groove extending sinuously or straightly. The groove may be divided into a plurality of branches.

The hole 20D has an area larger than that of each of the first trenches 20Ca and each of the second trenches 20Cb as viewed along the thickness direction 101. That is, the hole 20D has an area larger than that of each of one first trench 20Ca and one second trench 20Cb as viewed along the thickness direction 101.

The hole 20D has a width larger than a width of each of one first trench 20Ca and one second trench 20Cb. In this regard, the width of the hole 20D is defined as follows, for example. In a case in which the hole 20D has a shape of a circle as viewed along the thickness direction 101, the width of the hole 20D is a diameter of the circle. In a case in which the hole 20D has a shape of a rectangle as viewed along the thickness direction 101, the width of the hole 20D is a length of a shorter side of the rectangle. In a case in which the hole 20D is a narrow groove as viewed along the thickness direction 101, the width of the hole 20D extends along a direction orthogonal to a direction in which the groove extends. The above-described definitions apply to the widths of the first trench 20Ca and the second trench 20Cb.

The width of the hole 20D is two or more times larger than the width of each of one first trench 20Ca and one second trench 20Cb. Preferably, the width of the hole 20D is five or more times larger than the width of each of one first trench 20Ca and one second trench 20Cb. More preferably, the width of the hole 20D is ten or more times larger than the width of each of one first trench 20Ca and one second trench 20Cb.

FIG. 2 illustrates one hole 20D, but the number of the holes 20D included in the semiconductor substrate 20 is not limited to one. The semiconductor substrate 20 may include a plurality of holes 20D. The semiconductor substrate 20 is not necessarily required to include the hole 20D.

The first capacitor portion 31 is provided in the recess 20Ea, in the first trenches 20Ca, and on the one main surface 20A. That is, the first capacitor portion 31 is provided at least in the first trenches 20Ca. The second capacitor portion 32 is provided in the recess 20Eb, in the second trenches 20Cb, and on the other main surface 20B. That is, the second capacitor portion 32 is provided at least in the second trenches 20Cb.

At least a part of the first capacitor portion 31 and at least a part of the second capacitor portion 32 are located so as to overlap with each other as viewed along the thickness direction 101. In the present embodiment, at least the whole part of the first capacitor portion 31 and at least the whole part of the second capacitor portion 32 are located so as to overlap with each other as viewed along the thickness direction 101.

A configuration of the first capacitor portion 31 is described below. Note that a configuration of the second capacitor portion 32 is similar to the configuration of the first capacitor portion 31. Hence, description of the second capacitor portion 32 is basically omitted, but is made as needed.

The first capacitor portion 31 includes a dielectric layer and an electrode layer. In the present embodiment, the first capacitor portion 31 includes two dielectric layers (a first dielectric layer 311 and a second dielectric layer 312) and three electrode layers (a first electrode layer 321, a second electrode layer 322, and a third electrode layer 323).

The dielectric layer includes dielectric. In the present embodiment, the dielectric layer includes dielectric such as silicon dioxide (SiO₂), silicon nitride (Si₃N₄), hafnium oxide (HfO₂), or aluminum oxide (AlO). The first dielectric layer 311 and the second dielectric layer 312 may include the same material or different materials.

The electrode layer includes a conductor. In the present embodiment, the electrode layer includes a conductor such as metal such as copper, low-resistance silicon (Si) such as n-type Si or p-type Si having conductivity, or polysilicon (Poly-Si). The first electrode layer 321, the second electrode layer 322, and the third electrode layer 323 may include the same material or different materials.

The first electrode layer 321 is provided in the recess 20Ea. In the present embodiment, the first electrode layer 321 includes low-resistance silicon (Si). As described above, the first electrode layer 321 includes the four first trenches 20Ca in portions forming parts of the one main surface 20A.

The first dielectric layer 311 is stacked on the first electrode layer 321 and the semiconductor substrate 20 so as to extend in and outside the four first trenches 20Ca. The first dielectric layer 311 is stacked on the first electrode layer 321 along the first trenches 20Ca in the four first trenches 20Ca. The first dielectric layer 311 is stacked on the first electrode layer 321 and the one main surface 20A of the semiconductor substrate 20 outside the four first trenches 20Ca.

The second electrode layer 322 is stacked on the first dielectric layer 311 so as to extend in and outside the four first trenches 20Ca. The second electrode layer 322 is stacked on the first dielectric layer 311 along the first trenches 20Ca in the four first trenches 20Ca.

The second dielectric layer 312 is stacked on the second electrode layer 322 so as to extend in and outside the four first trenches 20Ca. The second dielectric layer 312 is stacked on the second electrode layer 322 along the first trenches 20Ca in the four first trenches 20Ca.

The third electrode layer 323 is stacked on the second dielectric layer 312 so as to extend in and outside the four first trenches 20Ca. The third electrode layer 323 is stacked on the second dielectric layer 312 so as to fill gaps not illustrated, in the first dielectric layer 311, the second electrode layer 322, and the second dielectric layer 312 in the four first trenches 20Ca.

As a result of the above-described stack of the dielectric layers and the electrode layers, the first dielectric layer 311 is sandwiched between the first electrode layer 321 and the second electrode layer 322, and the second dielectric layer 312 is sandwiched between the second electrode layer 322 and the third electrode layer 323. That is, the first capacitor portion 31 includes at least a dielectric layer and two electrode layers between which the dielectric layer is sandwiched. In the present embodiment, the first capacitor portion 31 includes two sets each including a dielectric layer and two electrode layers between which the dielectric layer is sandwiched. One of the two sets includes the first dielectric layer 311, and the first electrode layer 321 and the second electrode layer 322 between which the first dielectric layer 311 is sandwiched. The other of the two sets includes the second dielectric layer 312, and the second electrode layer 322 and the third electrode layer 323 between which the second dielectric layer 312 is sandwiched.

The second capacitor portion 32, like the first capacitor portion 31, includes two dielectric layers (the first dielectric layer 311 and the second dielectric layer 312) and three electrode layers (the first electrode layer 321, the second electrode layer 322, and the third electrode layer 323).

The first electrode layer 321 of the second capacitor portion 32 is provided in the recess 20Eb. The first electrode layer 321 of the second capacitor portion 32 includes the four second trenches 20Cb in portions forming parts of the other main surface 20B as described above.

The first dielectric layer 311, the second electrode layer 322, the second dielectric layer 312, and the third electrode layer 323 (in other words, each layer of the second capacitor portion 32) of the second capacitor portion 32 are stacked in the same manner as the first dielectric layer 311, the second electrode layer 322, the second dielectric layer 312, and the third electrode layer 323 of the first capacitor portion 31. The respective layers of the second capacitor portion 32 are stacked so as to extend in and outside the four second trenches 20Cb.

Alternatively, the first capacitor portion 31 and the second capacitor portion 32 may each include only one set of a dielectric layer and two electrode layers between which the dielectric layer is sandwiched, or may include three or more sets. Further, the number of dielectric layers and the number of electrode layers included in the first capacitor portion 31 may be the same as, or different from, the number of dielectric layers and the number of electrode layers included in the second capacitor portion 32.

The filling portion 40 is provided in the hole 20D. The filling portion 40 extends from one end to the other end of the hole 20D along the thickness direction 101. An upper surface 40A of the filling portion 40 is a portion of the filling portion 40 located at the one end of the hole 20D in the thickness direction 101. The upper surface 40A of the filling portion 40 forms a part of the one main surface 20A of the semiconductor substrate 20. A lower surface 40B of the filling portion 40 is a portion of the filling portion 40 located at the other end of the hole 20D in the thickness direction 101. The lower surface 40B of the filling portion 40 forms a part of the other main surface 20B of the semiconductor substrate 20.

The filling portion 40 includes a conductive material. In the present embodiment, the filling portion 40 includes a conductive layer 42 including copper as a conductive material. Note that the filling portion 40 includes only a conductive material in the present embodiment, but the filling portion 40 may include a material other than a conductive material. An example in which the filling portion 40 includes a material other than a conductive material is described later.

The semiconductor device 10 is not necessarily required to include the filling portion 40. In this case, the semiconductor substrate 20 is not necessarily required to include the hole 20D.

The first insulating layer 53 and the second insulating layer 54 include an insulator. The first insulating layer 53 and the second insulating layer 54 may be either an inorganic material or an organic material as long as the material has a high insulation property. In the present embodiment, each of the first insulating layer 53 and the second insulating layer 54 is provided in the one main surface 20A and the other main surface 20B.

The first insulating layer 53 provided in the one main surface 20A is stacked so as to cover a part of a portion exposed to the one main surface 20A in each layer (the first electrode layer 321, the second electrode layer 322, the third electrode layer 323, the first dielectric layer 311, and the second dielectric layer 312) of the first capacitor portion 31. The first insulating layer 53 provided in the other main surface 20B is stacked so as to cover a part of a portion exposed to the other main surface 20B in each layer (the first electrode layer 321, the second electrode layer 322, the third electrode layer 323, the first dielectric layer 311, and the second dielectric layer 312) of the second capacitor portion 32.

The second insulating layer 54 provided in the one main surface 20A is stacked so as to cover a part of the one main surface 20A, the first insulating layer 53, and a part of a portion exposed to the one main surface 20A in each of the second dielectric layer 312, the second electrode layer 322, and the third electrode layer 323 of the first capacitor portion 31. The second insulating layer 54 provided in the other main surface 20B is stacked so as to cover a part of the other main surface 20B, the first insulating layer 53, and a part of a portion exposed to the other main surface 20B in each of the second dielectric layer 312, the second electrode layer 322, and the third electrode layer 323 of the second capacitor portion 32.

The external terminals 51 are provided in at least one of the one main surface 20A or the other main surface 20B. Alternatively, the external terminals 51 may be provided in the side surface 20F. In the present embodiment, the external terminals 51 are provided in the one main surface 20A and the other main surface 20B. The external terminals 51 include a conductive material such as nickel (Ni) or gold (Au). In the present embodiment, the external terminals 51 each have a multilayer configuration of copper (Cu), nickel, and gold.

In the present embodiment, the external terminals 51 include a first external terminal 511, a second external terminal 512, a third external terminal 513, a fourth external terminal 514, a fifth external terminal 515, and a sixth external terminal 516. In the present embodiment, the first external terminal 511, the second external terminal 512, and the third external terminal 513 are provided on a side closer to the one main surface 20A of the semiconductor substrate 20. In the present embodiment, the fourth external terminal 514, the fifth external terminal 515, and the sixth external terminal 516 are provided on a side closer to the other main surface 20B of the semiconductor substrate 20. The first external terminal 511, the second external terminal 512, the third external terminal 513, the fourth external terminal 514, the fifth external terminal 515, and the sixth external terminal 516 include the same material in the present embodiment, but may include different materials.

The first external terminal 511, the second external terminal 512, and the third external terminal 513 are insulated from each other by the second insulating layer 54 on the side closer to the one main surface 20A. The fourth external terminal 514, the fifth external terminal 515, and the sixth external terminal 516 are insulated from each other by the second insulating layer 54 on the side closer to the other main surface 20B.

The first external terminal 511 is stacked on the first electrode layer 321 and the third electrode layer 323 of the first capacitor portion 31, and the first insulating layer 53. Thus, the first external terminal 511 is in contact with the first electrode layer 321 and the third electrode layer 323 of the first capacitor portion 31. That is, the first electrode layer 321 and the third electrode layer 323 of the first capacitor portion 31 are electrically connected to each other via the first external terminal 511.

Meanwhile, the first insulating layer 53 is provided between the first external terminal 511 and each of the first dielectric layer 311, the second electrode layer 322, and the second dielectric layer 312 of the first capacitor portion 31. Thus, the first external terminal 511, and each of the first dielectric layer 311, the second electrode layer 322, and the second dielectric layer 312 of the first capacitor portion 31, are insulated from each other by the first insulating layer 53.

The second external terminal 512 is stacked on the second electrode layer 322 of the first capacitor portion 31. Thus, the second external terminal 512 and the second electrode layer 322 of the first capacitor portion 31 are in contact with each other and are electrically connected to each other.

The third external terminal 513 is stacked on the upper surface 40A of the filling portion 40. Thus, the third external terminal 513 and the filling portion 40 are in contact with each other and are electrically connected to each other.

The fourth external terminal 514 is stacked on the first electrode layer 321 and the third electrode layer 323 of the second capacitor portion 32, and the first insulating layer 53. Thus, the fourth external terminal 514 is in contact with the first electrode layer 321 and the third electrode layer 323 of the second capacitor portion 32. That is, the first electrode layer 321 and the third electrode layer 323 of the second capacitor portion 32 are electrically connected to each other via the fourth external terminal 514.

Meanwhile, the first insulating layer 53 is provided between the fourth external terminal 514 and each of the first dielectric layer 311, the second electrode layer 322, and the second dielectric layer 312 of the second capacitor portion 32. Thus, the fourth external terminal 514, and each of the first dielectric layer 311, the second electrode layer 322, and the second dielectric layer 312 of the second capacitor portion 32 are insulated from each other by the first insulating layer 53.

The fifth external terminal 515 is stacked on the second electrode layer 322 of the second capacitor portion 32. Thus, the fifth external terminal 515 and the second electrode layer 322 of the second capacitor portion 32 are in contact with each other and are electrically connected to each other.

The sixth external terminal 516 is stacked on the lower surface 40B of the filling portion 40. Thus, the sixth external terminal 516 and the filling portion 40 are in contact with each other and are electrically connected to each other.

In the present embodiment, the semiconductor device 10 is mounted on a printed board (not illustrated) or the like via the external terminals 51 provided in the one main surface 20A and the other main surface 20B. That is, in the present embodiment, the one main surface 20A and the other main surface 20B are mounting surfaces of the semiconductor device 10. However, the side surface 20F may be a mounting surface of the semiconductor device 10. In this case, the external terminals 51 are provided in the side surface 20F of the semiconductor substrate 20, and the semiconductor device 10 is mounted on a printed board or the like via the external terminals 51 provided in the side surface 20F.

FIG. 3 is an equivalent circuit diagram of the semiconductor device according to the embodiment of the present disclosure. The semiconductor device 10 is configured as described above, and thus forms a circuit as illustrated in FIG. 3.

As illustrated in FIG. 3, a capacitor C1 is formed by the first dielectric layer 311 of the first capacitor portion 31, and the first electrode layer 321 and the second electrode layer 322 between which the first dielectric layer 311 is sandwiched. Further, a capacitor C2 is formed by the second dielectric layer 312 of the first capacitor portion 31, and the second electrode layer 322 and the third electrode layer 323 between which the second dielectric layer 312 is sandwiched.

One (the first electrode layer 321 of the first capacitor portion 31) of electrodes of the capacitor C1 and one (the third electrode layer 323 of the first capacitor portion 31) of electrodes of the capacitor C2 are connected to the first external terminal 511 (a terminal T3 in FIG. 2 and FIG. 3). The respective other electrodes (the second electrode layer 322 of the first capacitor portion 31) of the capacitors C1 and C2 are connected to the second external terminal 512 (a terminal T4 in FIG. 2 and FIG. 3).

One (the first electrode layer 321 of the second capacitor portion 32) of electrodes of a capacitor C3 and one (the third electrode layer 323 of the second capacitor portion 32) of electrodes of a capacitor C4 are connected to the fourth external terminal 514 (a terminal T5 in FIG. 2 and FIG. 3). The respective other electrodes (the second electrode layer 322) of the capacitors C3 and C4 are connected to the fifth external terminal 515 (a terminal T6 in FIG. 2 and FIG. 3).

The filling portion 40 forms a resistor R. The resistor R has one end (the upper surface 40A of the filling portion 40) connected to the third external terminal 513 (a terminal T1 in FIG. 2 and FIG. 3). The resistor R has the other end (the lower surface 40B of the filling portion 40) connected to the sixth external terminal 516 (a terminal T2 in FIG. 2 and FIG. 3).

The semiconductor device 10 described above has, for example, the following size. Specifically, a length along the thickness direction 101 is 0.15 mm, a length along a width direction 102 is 0.6 mm, and a length along a depth direction orthogonal to the thickness direction 101 and the width direction 102 is 0.3 mm. The first trench 20Ca and the second trench 20Cb each have a depth (a length along the thickness direction 101) of 30 μm. The electrode layers (the first electrode layer 321, the second electrode layer 322, and the third electrode layer 323) each have a thickness of 1000 nm. Note that, in a case in which the electrode layers include titanium nitride (TiN), the electrode layers each have a thickness of 20 nm. The dielectric layers (the first dielectric layer 311 and the second dielectric layer 312) each have a thickness of 10 nm.

### Method for Manufacturing Semiconductor Device

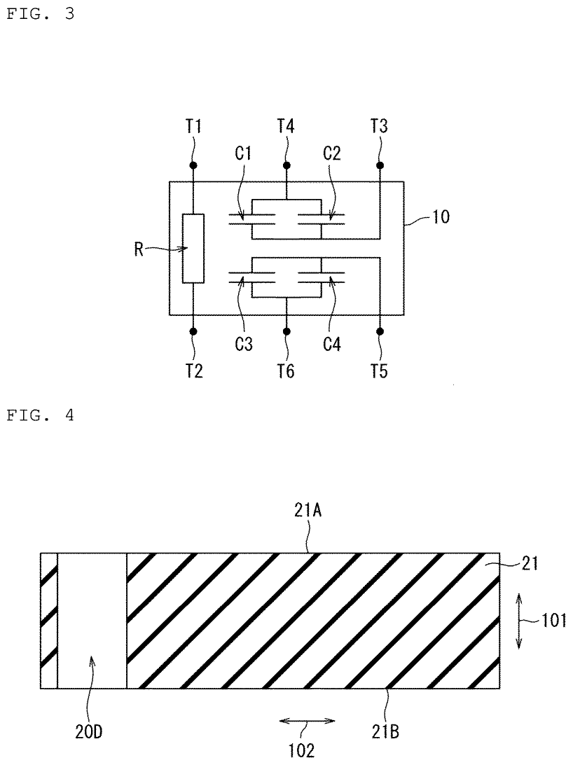

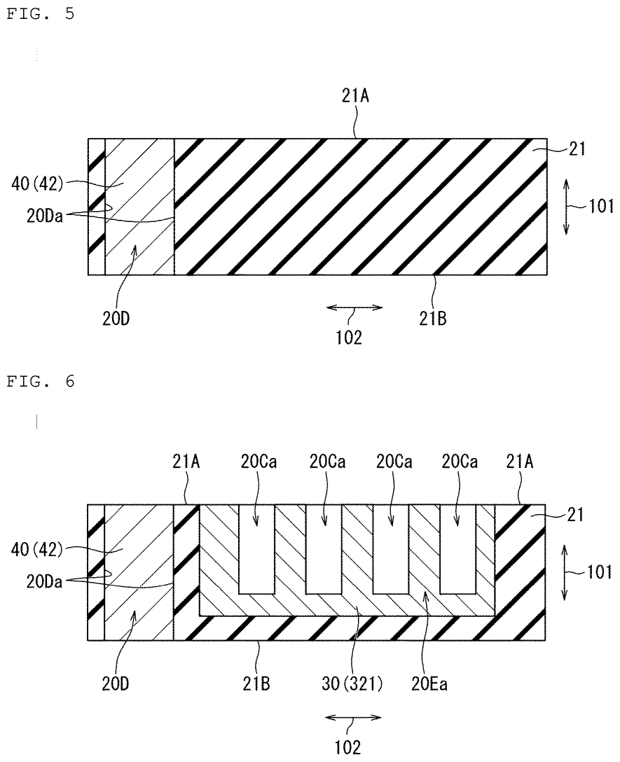

A method for manufacturing the semiconductor device 10 according to the embodiment of the present disclosure is described with reference to FIG. 4 to FIG. 11 and FIG. 2. FIG. 4 to FIG. 11 are schematic sectional views for illustrating the method for manufacturing the semiconductor device according to the embodiment of the present disclosure.

The semiconductor device 10 is manufactured by segmentation of a layered structure into individual pieces. The layered structure is a structure in which a plurality of the semiconductor devices 10 being arranged are integrated. FIG. 4 to FIG. 11 illustrate only a portion corresponding to one of the semiconductor devices 10 in the layered structure for the sake of convenience in description. The method for manufacturing the semiconductor device 10 according to the present embodiment includes a hole forming step, a filling-portion forming step, a recess forming step, a capacitor-portion forming step (an electrode-layer forming step, a dielectric-layer forming step, and a trench forming step), a first-insulating-layer forming step, a second-insulating-layer forming step, an external-terminal forming step, a bonding step, and a segmenting step.

In the hole forming step, the filling-portion forming step, the recess forming step, the capacitor-portion forming step, the first-insulating-layer forming step, the second-insulating-layer forming step, and the external-terminal forming step, a first substrate 21 and a second substrate 22 are manufactured. In the bonding step, the two substrates (the first substrate 21 and the second substrate 22) are bonded, thereby manufacturing the semiconductor substrate 20. In the present exemplary manufacturing method, the first substrate 21 and the second substrate 22 have the same configuration. Hence, in the following description of the hole forming step, the filling-portion forming step, the capacitor-portion forming step, the first-insulating-layer forming step, the second-insulating-layer forming step, and the external-terminal forming step, a process for manufacturing the first substrate 21 is described. Meanwhile, description of a process for manufacturing the second substrate 22 is basically omitted, but is made as needed.

### Hole Forming Step

First, the hole forming step is performed. In the hole forming step, as illustrated in FIG. 4, the hole 20D drilled through the first substrate 21 along the thickness direction 101 is formed in the first substrate 21. For example, a hard mask is formed over the first substrate 21, the hard mask is patterned so as to correspond to the hole 20D, and deep silicon etching is performed, so that the hole 20D is formed in the first substrate 21. After the deep silicon etching is performed, the hard mask is removed.

### Filling-Portion Forming Step

Subsequently, the filling-portion forming step is performed. In the filling-portion forming step, as illustrated in FIG. 5, the hole 20D is filled with conductive paste. This paste corresponds to the conductive layer 42 of the filling portion 40. For example, seeds are formed, filled via plating is performed, the seeds are removed, and flattening is performed, so that the filling portion 40 is formed. Note that filling with the filling portion 40 can be achieved by a process other than the forming process as described above. For example, filling may be achieved using a conductive material such as copper (Cu) or aluminum (Al), as the filling portion 40, by a process such as sputtering, wet plating, and a paste process.

### Capacitor-Portion Forming Step

Subsequently, the capacitor-portion forming step is performed. The capacitor-portion forming step is divided into an electrode-layer forming step, a dielectric-layer forming step, and a trench forming step. The capacitor-portion forming step in manufacture of the first substrate 21 is an example of a first-capacitor-portion forming step. The capacitor-portion forming step in manufacture of the second substrate 22 is an example of a second-capacitor-portion forming step. The trench forming step in manufacture of the first substrate 21 is an example of a first-trench forming step. The trench forming step in manufacture of the second substrate 22 is an example of a second-trench forming step.

In the capacitor-portion forming step, the electrode-layer forming step and the dielectric-layer forming step are alternately performed. The trench forming step is performed after the first time of the electrode-layer forming step and before the first time of the dielectric-layer forming step.

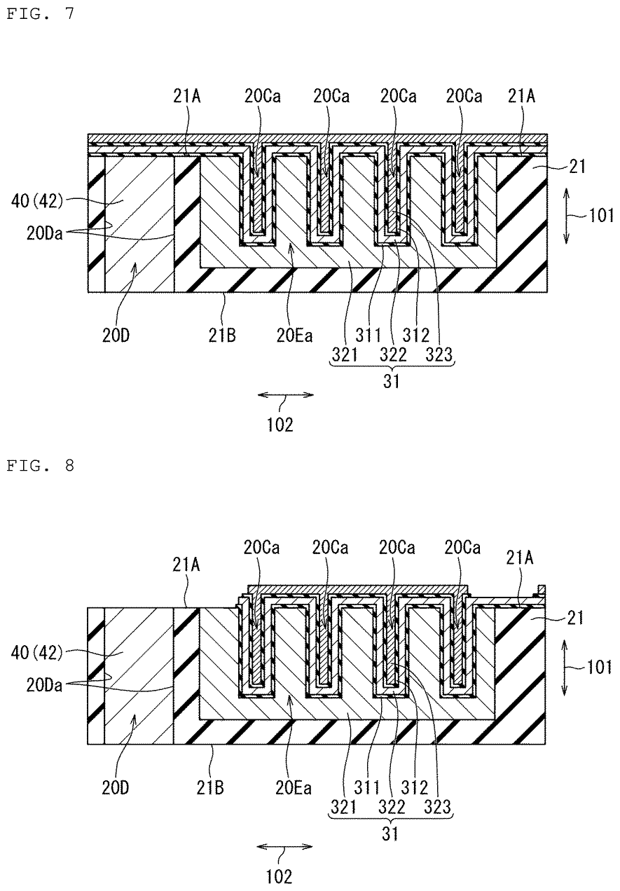

In the first time of the electrode-layer forming step, as illustrated in FIG. 6, the semiconductor substrate 20 that is a high-resistance portion including high-resistance Si is doped with impurities. As a result, the recess 20Ea is formed in the semiconductor substrate 20 that is a high-resistance portion, and the first electrode layer 321 as a low-resistance portion is formed in the recess 20Ea. For formation of the first electrode layer 321, for example, a patterned resist is formed at a position of the recess 20Ea, silicon etching using impurity-doped silicon is performed, and the resist is removed. The first electrode layer 321 forms a part of one main surface 21A of the first substrate 21.

In the trench forming step, the four first trenches 20Ca are formed in parts of the one main surface 21A in the first electrode layer 321. The first trenches 20Ca are formed by, for example, patterning of a hard mask and deep silicon etching, in the same manner as the hole 20D. Note that, in the trench forming step in manufacture of the second substrate 22, the four second trenches 20Cb are formed in the first electrode layer 321.

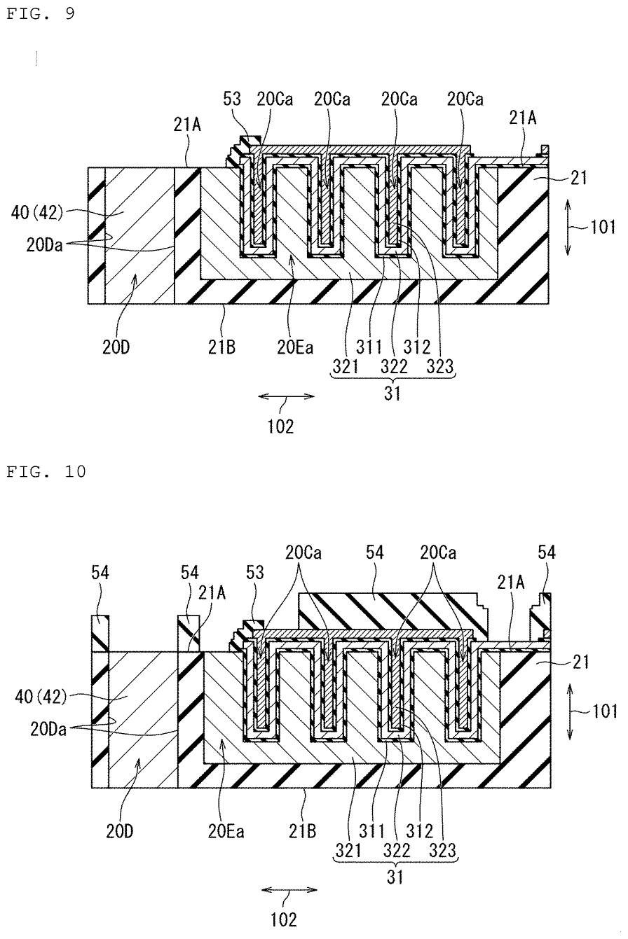

Subsequently, the dielectric-layer forming step and the electrode-layer forming step are alternately performed. As a result, dielectric layers and electrode layers are alternately stacked (deposited) along the one main surface 20A of the first substrate 21 and a surface defining the first trenches 20Ca. Specifically, as illustrated in FIG. 7, the first dielectric layer 311 is formed on the first substrate 21, the filling portion 40, and the first electrode layer 321. The second electrode layer 322 is formed on the first dielectric layer 311. The second dielectric layer 312 is formed on the second electrode layer 322. The third electrode layer 323 is formed on the second dielectric layer 312.

By the above-described processes, in the capacitor-portion forming step in manufacture of the first substrate 21, the first capacitor portion 31 including a dielectric layer and two electrode layers between which the dielectric layer is sandwiched is formed at least in the first trenches 20Ca in the first substrate 21. Likewise, in the capacitor-portion forming step in manufacture of the second substrate 22, the second capacitor portion 32 including a dielectric layer and two electrode layers between which the dielectric layer is sandwiched is formed at least in the second trenches 20Cb in the second substrate 22.

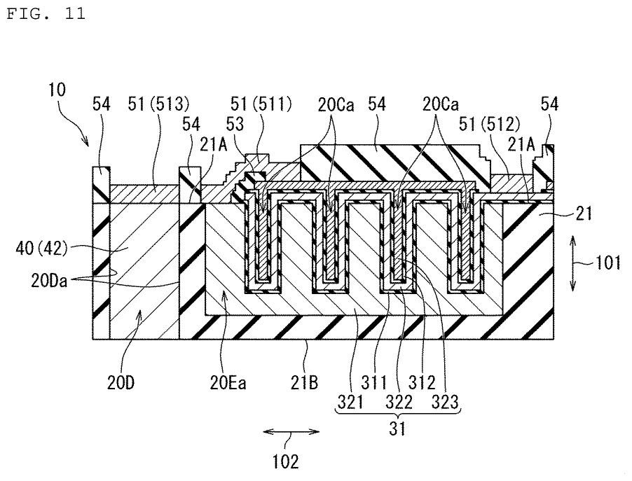

In the dielectric-layer forming step and the electrode-layer forming step, after the dielectric layers 311 and 312 and the electrode layers 322 and 323 are formed, the dielectric layers 311 and 312 and the electrode layers 322 and 323 are subjected to photolithography and etching. As a result, a part of each of the dielectric layers 311 and 312 and each of the electrode layers 322 and 323 is removed as illustrated in FIG. 8.

Note that, in the present embodiment, the trench forming step is defined as a part of the capacitor-portion forming step. However, the trench forming step may be defined as a step separate from the capacitor-portion forming step. In this case, the capacitor-portion forming step is divided into the electrode-layer forming step and the dielectric-layer forming step. Then, the trench forming step is performed after the electrode-layer forming step in the first time of the capacitor-portion forming step is performed, and thereafter, a remaining step in the capacitor-portion forming step is performed.

### First-Insulating-Layer Forming Step

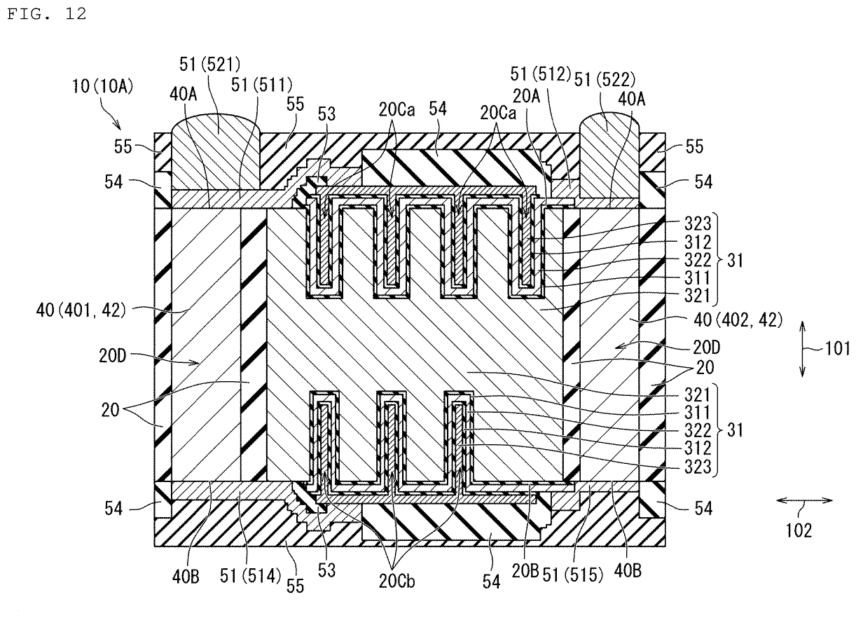

Subsequently, the first-insulating-layer forming step is performed. In the first-insulating-layer forming step, as illustrated in FIG. 9, the first insulating layer 53 is stacked. Specifically, the first insulating layer 53 is deposited on an upper surface in FIG. 8 (a surface closer to the one main surface 21A of the first substrate 21) and is subjected to photolithography and dry etching, to be patterned so as to be provided at a position of the first insulating layer 53 in FIG. 9.

### Second-Insulating-Layer Forming Step

Subsequently, the second-insulating-layer forming step is performed. In the second-insulating-layer forming step, as illustrated in FIG. 10, the second insulating layer 54 is stacked. Specifically, the second insulating layer 54 is deposited on an upper surface in FIG. 9 (a surface closer to the one main surface 21A of the first substrate 21) and is subjected to photolithography and dry etching, to be patterned so as to be provided at a position of the second insulating layer 54 in FIG. 10. Note that the second-insulating-layer forming step may be performed before the first-insulating-layer forming step, or may be performed in parallel with the first-insulating-layer forming step.

The first insulating layer 53 and the second insulating layer 54 may be formed by a process other than deposition such as chemical vapor deposition (CVD), for example, a known process such as spin coating or film lamination. Further, a protective layer that is an insulating layer may be further provided on the second insulating layer 54 as needed. For example, the protective layer is epoxy, polyimide, or acrylic organic resin.

### External-Terminal Forming Step

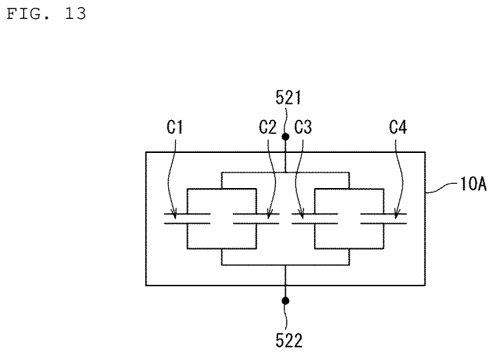

Subsequently, the external-terminal forming step is performed. In the external-terminal forming step, as illustrated in FIG. 11, the first external terminal 511, the second external terminal 512, and the third external terminal 513) among the external terminals 51 are formed. Specifically, a conductive layer serving as the external terminals 51 is formed at a predetermined position (a position illustrated in FIG. 2) in an upper surface in FIG. 10 (a surface closer to the one main surface 21A of the first substrate 21) by a known process such as metal sputtering, electroless plating, or a paste process. In the external-terminal forming step in manufacture of the second substrate 22, the fourth external terminal 514, the fifth external terminal 515, and the sixth external terminal 516) among the external terminals 51 are formed.

Note that the external terminals 51 may each include a plurality of conductive layers. In a case in which the external terminals 51 each include a plurality of conductive layers, the external terminal 51 has improved barrier performance and solder wettability while keeping electromigration resistance of the external terminal 51.

### Bonding Step

Subsequently, the bonding step is performed. In the bonding step, as illustrated in FIG. 2, the other main surface 21B of the first substrate 21 and the other main surface 22B of the second substrate 22 are bonded, thereby manufacturing one semiconductor substrate 20. The other main surface 21B is a surface opposite to the one main surface 21A along the thickness direction 101 and faces in a direction opposite to the one main surface 21A. The other main surface 22B is a surface opposite to one main surface 22A along the thickness direction 101 and faces in a direction opposite to the one main surface 22A. The other main surface 21B is an example of a rear surface with respect to a main surface of the first substrate. The other main surface 22B is an example of a rear surface with respect to a main surface of the second substrate. Note that, in the semiconductor substrate 20 in which the first substrate 21 and the second substrate 22 have been bonded, an interface between the first substrate 21 and the second substrate 22 can be eliminated. Thus, in the drawings, the interface between the first substrate 21 and the second substrate 22 is indicated by a broken line.

Before the first substrate 21 and the second substrate 22 are bonded, the first substrate 21 and the second substrate 22 are ground and polished, and thus the lengths of the first substrate 21 and the second substrate 22 along the thickness direction 101 are adjusted. At that time, the other main surface 21B of the first substrate 21 and the other main surface 22B of the second substrate 22 are sufficiently flattened, making it easier to bond the first substrate 21 and the second substrate 22 in the bonding step. Alternatively, as an activation process, a functional group, a partially sputtered film, or the like may be formed in order to increase the bonding strength.

After the first substrate 21 and the second substrate 22 are ground and polished, the other main surface 21B of the first substrate 21 and the other main surface 22B of the second substrate 22 are bonded. The bonding is achieved by a known process such as thermocompression bonding or adhesion.

Note that, in the present manufacturing method, the first substrate 21 and the second substrate 22 are bonded because no chip component or the like is mounted on the other main surface 21B or 22B. However, in a case in which a chip component or the like is mounted on at least one of the other main surface 21B or 22B, the first substrate 21 and the second substrate 22 may be bonded with the chip component or the like interposed therebetween. For example, in a case in which a chip component or the like is mounted on one of the other main surfaces 21B and 22B, the chip component or the like and the other of the other main surfaces 21B and 22B may be bonded. Alternatively, for example, in a case in which a chip component or the like is mounted on each of the other main surfaces 21B and 22B, the chip component or the like mounted on the other main surface 21B and the chip component or the like mounted on the other main surface 22B may be bonded.

### Segmenting Step

Subsequently, the segmenting step is performed. In the segmenting step, a layered structure in which the plurality of semiconductor devices 10 are arranged is cut into the plurality of semiconductor devices 10.

Note that, in the above-described example of the manufacturing method, the semiconductor substrate 20 is manufactured through the bonding step of bonding two substrates (the first substrate 21 and the second substrate 22) in each of which trenches and a capacitor portion have been formed, but the bonding step may be omitted. In this case, one sheet of a substrate is manufactured, instead of two sheets of substrates. Specifically, in the recess forming step, the recess 20Ea is formed in the one main surface 20A of the semiconductor substrate 20, and the recess 20Eb is formed in the other main surface 20B of the semiconductor substrate 20. Further, in the capacitor-portion forming step, the first capacitor portion 31 is formed in the one main surface 20A of the semiconductor substrate 20, and the second capacitor portion 32 is formed in the other main surface 20B of the semiconductor substrate 20. Moreover, in the trench forming step, the first trenches 20Ca are formed on the side closer to the one main surface 20A of the semiconductor substrate 20, and the second trenches 20Cb are formed on the side closer to the other main surface 20B of the semiconductor substrate 20.

According to the present embodiment, the trenches (the first trenches 20Ca and the second trenches 20Cb) are provided in both the one main surface 20A and the other main surface 20B of the semiconductor substrate 20. Further, the first capacitor portion 31 is provided in the first trenches 20Ca, and the second capacitor portion 32 is provided in the second trenches 20Cb. This enables an increase in capacitance of the capacitor portions (the first capacitor portion 31 and the second capacitor portion 32), as compared with that in a configuration in which a trench is provided in only one surface of a substrate and a capacitor portion is provided in the trench.

According to the present embodiment, the filling portion 40 including a conductive material can function as a shield against noises. Thus, the filling portion 40 can reduce noises coming from the outside of the first capacitor portion 31 and the second capacitor portion 32 toward the first capacitor portion 31 and the second capacitor portion 32 via the filling portion 40.

By using the filling portion 40 as a wire in the semiconductor device 10, it is possible to reduce wires routed in the semiconductor device 10. This enables reduction in the parasitic capacitance generated in the semiconductor device 10. Further, by using the filling portion 40 as a wire in the semiconductor device 10, it is possible to use the filling portion 40 for extracting a signal from the semiconductor device 10, which improves the design flexibility of the semiconductor device 10.

According to the present embodiment, the hole 20D has an area larger than an area of each of one first trench 20Ca and one second trench 20Cb as viewed along the thickness direction 101. This enables reduction in variations in manufacture of the hole 20D. This makes it easy to fill the hole 20D with the filling portion 40. Further, because of the large area of the hole 20D as viewed along the thickness direction 101, the hole 20D having a great depth can be easily formed.

In a capacitor disclosed in Japanese Patent No. 7052867, a dielectric film and a conductor film are provided on a front surface side of a substrate, and thus it is not necessarily easy to handle a signal from a rear surface of the substrate. In contrast, according to the present embodiment, the hole 20D opens to both the one main surface 20A and the other main surface 20B, in other words, the hole 20D is drilled through the semiconductor substrate 20 along the thickness direction 101. In this case, it is easy to handle a signal from the other main surface 20B for the first capacitor portion 31 provided on the side closer to the one main surface 20A. Further, it is easy to handle a signal from the one main surface 20A for the second capacitor portion 32 provided on the side closer to the other main surface 20B.

According to the present embodiment, in mounting the semiconductor device 10 on a board via paste such as solder, the paste is deposited on the external terminals 51, which facilitates mounting.

According to the present embodiment, the area of the semiconductor device 10 as viewed along the thickness direction 101 can be reduced as compared with a configuration in which the first capacitor portion 31 and the second capacitor portion 32 are located so as not to overlap each other as viewed along the thickness direction 101.

According to the present manufacturing method, the semiconductor device 10 is manufactured by bonding of two sheets of substrates (the first substrate 21 and the second substrate 22). This can facilitate manufacture of the semiconductor device 10.

Now, modifications of the present embodiment and a configuration of a module unit 70 are described below. In the following description, the components described above are denoted by the same reference signs, and description thereof is basically omitted, but is made as needed.

### First Modification of Semiconductor Device

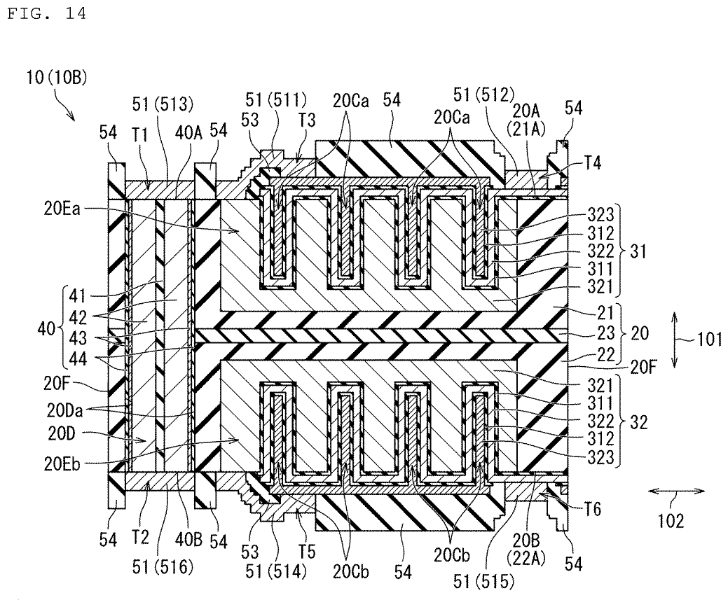

FIG. 12 is a schematic sectional view of a modification of the semiconductor device according to the embodiment of the present disclosure.

A semiconductor device 10A in a first modification may include the external terminal 51 protruding more than another portion. For example, as illustrated in FIG. 12, the semiconductor device 10A includes a first columnar external terminal 521 and a second columnar external terminal 522 each having a shape of a column, as the external terminal 51 protruding more than another portion. Further, the semiconductor device 10A may include an insulating protective layer covering at least one of the one main surface 20A or the other main surface 20B. For example, as illustrated in FIG. 12, the semiconductor device 10A includes an insulating protective film 55 that is provided on the one main surface 20A and the other main surface 20B and covers both the one main surface 20A and the other main surface 20B.

The first columnar external terminal 521 is provided on the first external terminal 511. That is, the first columnar external terminal 521 is provided in the one main surface 20A with the first external terminal 511 interposed therebetween. The second columnar external terminal 522 is provided on the second external terminal 512. That is, the second columnar external terminal 522 is provided in the one main surface 20A with the second external terminal 512 interposed therebetween. The first columnar external terminal 521 and the second columnar external terminal 522 are examples of a specific external terminal. The one main surface 20A is an example of a specific main surface.

The first columnar external terminal 521 and the second columnar external terminal 522 protrude with respect to the one main surface 20A along the thickness direction 101.

A protrusion length of each of the first columnar external terminal 521 and the second columnar external terminal 522 with respect to the one main surface 20A along the thickness direction 101 is larger than a protrusion length of another portion provided in the one main surface 20A with respect to the one main surface 20A along the thickness direction 101. In this regard, another portion is any portion provided in the one main surface 20A other than the first columnar external terminal 521 and the second columnar external terminal 522. In the configuration illustrated in FIG. 12, another portion is the first capacitor portion 31, the first external terminal 511, the second external terminal 512, the first insulating layer 53, the second insulating layer 54, or the protective film 55.

In the configuration illustrated in FIG. 12, each of the first columnar external terminal 521 and the second columnar external terminal 522 among the external terminals 51 corresponds to the specific external terminal. However, another external terminal 51 (the first external terminal 511, the second external terminal 512, the third external terminal 513, the fourth external terminal 514, the fifth external terminal 515, or the sixth external terminal 516) may correspond to the specific external terminal. That is, at least one of the external terminals 51 may correspond to the specific external terminal. The specific external terminal protrudes with respect to the specific main surface along the thickness direction 101, and has a protrusion length larger than that of another portion.

In the configuration illustrated in FIG. 12, each of the first columnar external terminal 521 and the second columnar external terminal 522 is provided as the specific external terminal in the one main surface 20A. However, the specific external terminal may be provided in the other main surface 20B. The specific external terminal may be provided in both the one main surface 20A and the other main surface 20B.

The protective film 55 provided on the one main surface 20A covers the first capacitor portion 31, the first external terminal 511, the second external terminal 512, the first insulating layer 53, and the second insulating layer 54. Further, the protective film 55 provided on the one main surface 20A covers only portions of the first columnar external terminal 521 and the second columnar external terminal 522 other than respective tip ends thereof. Thus, the respective tip ends of the first columnar external terminal 521 and the second columnar external terminal 522 protrude with respect to the protective film 55 along the thickness direction 101 and are exposed to the outside of the semiconductor device 10A. Consequently, the protective film 55 provided on the one main surface 20A does not entirely cover the one main surface 20A.

The protective film 55 provided on the other main surface 20B covers the first capacitor portion 31, the first external terminal 511, the second external terminal 512, the first insulating layer 53, and the second insulating layer 54. That is, the protective film 55 provided on the other main surface 20B entirely covers the other main surface 20B.

Consequently, the protective film 55 does not cover the one main surface 20A while covering the other main surface 20B of the one main surface 20A and the other main surface 20B. Alternatively, the protective film 55 may be provided so as not to cover the other main surface 20B while covering the one main surface 20A of the one main surface 20A and the other main surface 20B. Further alternatively, the protective film 55 may entirely cover both the one main surface 20A and the other main surface 20B.

The semiconductor device 10A includes two holes 20D and two filling portions 40. The two filling portions 40 are a first filling portion 401 and a second filling portion 402. One of the two holes 20D is filled with the first filling portion 401. The other of the two holes 20D is filled with the second filling portion 402.

The semiconductor device 10A includes the first external terminal 511, the second external terminal 512, the fourth external terminal 514, and the fifth external terminal 515, but does not include the third external terminal 513 or the sixth external terminal 516.

The first external terminal 511 is in contact with the first filling portion 401 and the first columnar external terminal 521 in addition to the first electrode layer 321 and the third electrode layer 323 of the first capacitor portion 31. The fourth external terminal 514 is in contact with the first filling portion 401 in addition to the first electrode layer 321 and the third electrode layer 323 of the second capacitor portion 32. Thus, the first electrode layer 321 and the third electrode layer 323 of the first capacitor portion 31, the first electrode layer 321 and the third electrode layer 323 of the second capacitor portion 32, and the first columnar external terminal 521 are electrically connected to each other via the first external terminal 511, the fourth external terminal 514, and the first filling portion 401.

The second external terminal 512 is in contact with the second filling portion 402 and the second columnar external terminal 522 in addition to the second electrode layer 322 of the first capacitor portion 31. The fifth external terminal 515 is in contact with the second filling portion 402 in addition to the second electrode layer 322 of the second capacitor portion 32. Thus, the second electrode layer 322 of the first capacitor portion 31, the second electrode layer 322 of the second capacitor portion 32, and the second columnar external terminal 522 are electrically connected to each other via the second external terminal 512, the fifth external terminal 515, and the second filling portion 402.

Consequently, the filling portion 40 is electrically connected to both the first capacitor portion 31 and the second capacitor portion 32.

In the semiconductor device 10A, materials of the first external terminal 511 and the second external terminal 512 located on the one main surface 20A are different from materials of the fourth external terminal 514 and the fifth external terminal 515 located on the other main surface 20B. The first external terminal 511 and the second external terminal 512 located on the one main surface 20A are an example of a first wiring layer. The fourth external terminal 514 and the fifth external terminal 515 located on the other main surface 20B are an example of a second wiring layer.

Note that materials of the first columnar external terminal 521 and the second columnar external terminal 522 may be the same as the materials of the first external terminal 511 and the second external terminal 512. Alternatively, the materials of the first columnar external terminal 521 and the second columnar external terminal 522 may be the same as the materials of the fourth external terminal 514 and the fifth external terminal 515. Further alternatively, the materials of the first columnar external terminal 521 and the second columnar external terminal 522 may be different from any of the materials of the first external terminal 511, the second external terminal 512, the fourth external terminal 514, and the fifth external terminal 515.

In the semiconductor device 10 of the above-described embodiment, the external terminal 51 has a multilayer configuration of copper (Cu), nickel, and gold, but in the semiconductor device 10A of the first modification, a material that has lower resistance and is more inexpensive, for example, aluminum (Al), is used. As a matter of course, the material of the external terminal 51 is not limited to aluminum, and metal that can tightly adhere to a seed layer, for example, titanium (Ti), can be selected at appropriate times as needed. For example, aluminum is used as the materials of the first external terminal 511 and the second external terminal 512, and titanium is used as the materials of the fourth external terminal 514 and the fifth external terminal 515.

In the semiconductor device 10A, the first electrode layer 321 of the first capacitor portion 31 and the first electrode layer 321 of the second capacitor portion 32 are integral with each other. Here, the term “integral” means that a boundary between the first electrode layer 321 of the first capacitor portion 31 and the first electrode layer 321 of the second capacitor portion 32 is indefinite, and the two electrode layers are electrically connected to each other. The first electrode layer 321 of the first capacitor portion 31 is an electrode layer that is one of the two electrode layers (the first electrode layer 321 and the second electrode layer 322) included in the first capacitor portion 31, is provided outside the first trenches 20Ca, and forms at least a part of the semiconductor substrate 20. The first electrode layer 321 of the second capacitor portion 32 is an electrode layer that is one of the two electrode layers (the first electrode layer 321 and the second electrode layer 322) included in the second capacitor portion 32, is provided outside the second trenches 20Cb, and forms at least a part of the semiconductor substrate 20.

The semiconductor device 10A includes four first trenches 20Ca and three second trenches 20Cb. That is, in the semiconductor device 10A, the number of the first trenches 20Ca is larger than the number of the second trenches 20Cb. Note that the number of the first trenches 20Ca is not limited to four, and the number of the second trenches 20Cb is not limited to three. The number of the second trenches 20Cb may be larger than the number of the first trenches 20Ca. Thus, in the semiconductor device 10A, the number of the first trenches 20Ca is different from the number of the second trenches 20Cb.

In the semiconductor device 10 of the above-described embodiment, each first trench 20Ca and each second trench 20Cb have the same size. However, each first trench 20Ca and each second trench 20Cb may have different sizes. The sizes of each first trench 20Ca and each second trench 20Cb (hereinafter referred to as each trench) are determined by, for example, an area and a shape of each trench as viewed along the thickness direction 101, a length of each trench along the thickness direction 101 (a depth of each trench), and the like. That is, the respective areas and shapes of the trenches as viewed along the thickness direction 101, the respective depths of the trenches, and the like may be different from each other.

For example, in the semiconductor device 10A, the area of each of the three second trenches 20Cb is smaller than an area of each of the four first trenches 20Ca as viewed along the thickness direction 101. Thus, in the semiconductor device 10A, the first trench 20Ca and the second trench 20Cb have different sizes.

In the semiconductor device 10A, the capacitance of the first capacitor portion 31 is larger than the capacitance of the second capacitor portion 32. That is, in the semiconductor device 10A, the capacitance of the first capacitor portion 31 is different from the capacitance of the second capacitor portion 32. In the semiconductor device 10A illustrated in FIG. 12, due to the difference in the size and number of the first trenches 20Ca and the second trenches 20Cb, the capacitance of the first capacitor portion 31 is larger than the capacitance of the second capacitor portion 32.

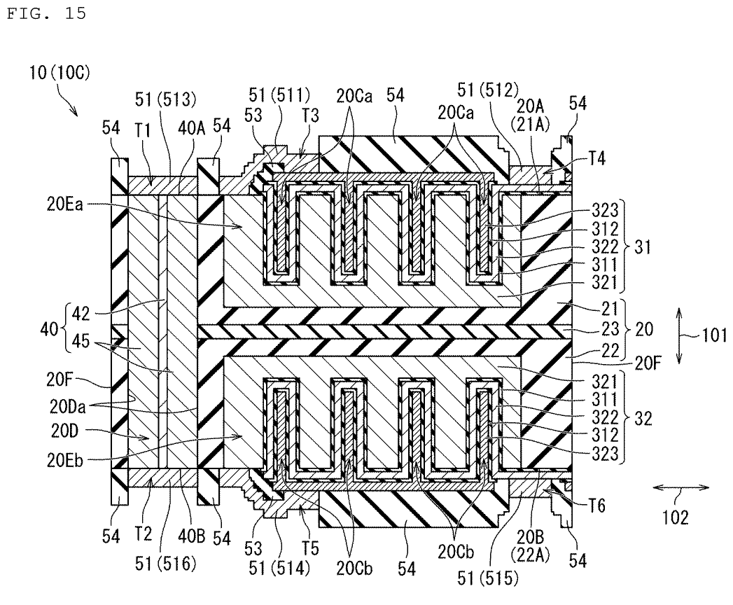

FIG. 13 is an equivalent circuit diagram of the semiconductor device illustrated in FIG. 12. The semiconductor device 10A is configured as described above, and thus forms a circuit as illustrated in FIG. 13. The capacitors C1 and C2 are connected in parallel, and the capacitors C3 and C4 are connected in parallel. One of the electrodes of each of the capacitors C1, C2, C3, and C4 is connected to the first columnar external terminal 521. The other of the electrodes of each of the capacitors C1, C2, C3, and C4 is connected to the second columnar external terminal 522.

According to the first modification, the filling portion 40 is electrically connected to both the first capacitor portion 31 and the second capacitor portion 32, which improves the design flexibility of the semiconductor device 10A.

According to the first modification, the first columnar external terminal 521 and the second columnar external terminal 522 protrude more than another portion. Hence, it is easy to bring a measurement needle into contact with the first columnar external terminal 521 and the second columnar external terminal 522. This can facilitate measurement.

According to the first modification, the electrode layer 321 is shared by the first trenches 20Ca and the second trenches 20Cb. This enables reduction in the size of the semiconductor device 10A as compared with a configuration in which the electrode layer 321 in the first trenches 20Ca and the electrode layer 321 in the second trenches 20Cb are provided separately from each other.

According to the first modification, the conductive portions (for example, the first capacitor portion 31, the second capacitor portion 32, and the external terminals 51) provided in each of the one main surface 20A and the other main surface 20B can be protected by the protective film 55. This can, for example, prevent foreign matters from being deposited on the conductive portions.

According to the first modification, the first wiring layer (the first external terminal 511 and the second external terminal 512) and the second wiring layer (the fourth external terminal 514 and the fifth external terminal 515) are laid, which improves the design flexibility of the semiconductor device 10A. The first wiring layer and the second wiring layer include different materials, and thus a material fit to a process of stacking the first wiring layer can be used as a material of the first wiring layer, and a material fit to a process of stacking the second wiring layer can be used as a material of the second wiring layer.

According to the first modification, the capacitance of the first capacitor portion 31 is different from the capacitance of the second capacitor portion 32. Thus, two different capacitance values can be obtained in the semiconductor device 10A.

### Second Modification of Semiconductor Device

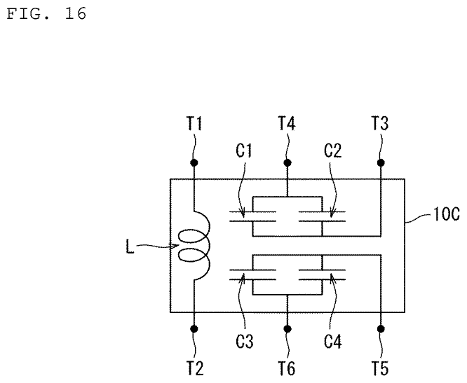

FIG. 14 is a schematic sectional view of a modification of the semiconductor device according to the embodiment of the present disclosure.

As illustrated in FIG. 14, the filling portion 40 may include a material other than a conductive material. The filling portion 40 illustrated in FIG. 14 includes a buried layer 41, a barrier layer 43, and an isolation layer 44 in addition to the conductive layer 42.

The buried layer 41 includes resin such as epoxy. The barrier layer 43 includes a conductive material such as titanium nitride (TiN) or nickel (Ni). The isolation layer 44 includes an insulating material such as silicon dioxide (SiO₂) or silicon nitride (Si₃N₄). That is, in the filling portion 40 of a semiconductor device 10B illustrated in FIG. 14, the conductive layer 42 and the barrier layer 43 forming a part of the filling portion 40 include a conductive material, and the buried layer 41 and the isolation layer 44 other than the above-mentioned part include no conductive material.

Each of the buried layer 41, the conductive layer 42, the barrier layer 43, and the isolation layer 44 penetrates the hole 20D along the thickness direction 101. In other words, each of the buried layer 41, the conductive layer 42, the barrier layer 43, and the isolation layer 44 extends from one end to the other end of the hole 20D along the thickness direction 101.

The conductive layer 42 surrounds the buried layer 41 as viewed along the thickness direction 101. The barrier layer 43 surrounds the conductive layer 42 as viewed along the thickness direction 101. The isolation layer 44 surrounds the barrier layer 43 as viewed along the thickness direction 101. An outer surface of the isolation layer 44 is in contact with the side surface 20Da of the hole 20D.

Alternatively, the filling portion 40 may omit at least one of the buried layer 41 or the barrier layer 43. Further alternatively, a magnetic layer 45 described later may be provided between two adjacent layers among the buried layer 41, the conductive layer 42, the barrier layer 43, and the isolation layer 44.

The semiconductor substrate 20 of the semiconductor device 10B includes the first substrate 21, the second substrate 22, and an adhesive layer 23. The first substrate 21 and the second substrate 22, like the semiconductor substrate 20 illustrated in FIG. 2, include high-resistance Si having an insulation property. The first substrate 21 includes the first trenches 20Ca. The second substrate 22 includes the second trenches 20Cb. The adhesive layer 23 is located between the first substrate 21 and the second substrate 22. The first substrate 21 and the second substrate 22 are bonded by the adhesive layer 23. The adhesive layer 23 may be organic resin such as polyimide, an inorganic oxide film, or a conductor layer having conductivity. In a case in which the adhesive layer 23 is a conductor layer, the adhesive layer 23 can be used as a routed wire between ground and electronic components.

The semiconductor device 10B is manufactured by the above-described manufacturing method for the most part. However, in the bonding step, the first substrate 21 and the second substrate 22 are bonded by adhesion. At that time, the adhesive layer 23 is formed. Further, the hole forming step, the filling-portion forming step, and the external-terminal forming step are performed after the bonding step. Note that the recess forming step, the capacitor-portion forming step, the first-insulating-layer forming step, and the second-insulating-layer forming step may also be performed after the bonding step.

In the hole forming step, for example, the hole 20D drilled through the semiconductor substrate 20 in which the first substrate 21 and the second substrate 22 adhere to each other via the adhesive layer 23, along the thickness direction 101, is formed using a microdrill or a laser.

In the subsequent filling-portion forming step, the respective layers forming the filling portion 40 are sequentially supplied in order from the outermost layer. Specifically, firstly, the isolation layer 44 is supplied to fill the hole 20D. Secondly, a hole drilled through the isolation layer 44 along the thickness direction 101 is formed using a microdrill or a laser, and the hole is filled with the barrier layer 43. After that, the conductive layer 42 and the buried layer 41 are supplied in the same manner.

In the subsequent external-terminal forming step, the third external terminal 513 is stacked on the upper surface 40A of the filling portion 40 having been supplied, and the sixth external terminal 516 is stacked on the lower surface 40B of the filling portion 40 having been supplied.

According to the second modification, the isolation layer 44 includes an insulating material. Thus, the isolation layer 44 can block transmission of a signal from the conductive layer 42 to another portion such as the first capacitor portion 31 and the second capacitor portion 32 via the semiconductor substrate 20.

The electrical resistance of the conductive layer 42 is likely to be changed due to, for example, diffusion of a conductive material (for example, copper) included in the conductive layer 42. According to the second modification, the barrier layer 43 can suppress diffusion of the conductive layer 42. This can reduce a change in the electric resistance of the conductive layer 42.

According to the second modification, the barrier layer 43 includes a conductive material, and thus the barrier layer 43 can function as a seed layer. Further, an electric signal can be passed through the barrier layer 43.

According to the second modification, because of inclusion of the buried layer 41 in the filling portion 40, it is possible to suppress undesired void formation, mixture with foreign matters, and irregularities in a portion exposed to the one main surface 20A and the other main surface 20B in the filling portion 40. That is, the inclusion of the buried layer 41 in the filling portion 40 eliminates a need to fill the whole of the hole 20D with the conductive layer 42. This enables reduction in a manufacturing cost of the semiconductor device 10.

According to the second modification, the semiconductor substrate 20 including the one main surface 20A and the other main surface 20B can be formed by bonding of the first substrate 21 and the second substrate 22 via the adhesive layer 23. This enables realization of the semiconductor device 10B having a high degree of accuracy at a low cost.

### Third Modification of Semiconductor Device

FIG. 15 is a schematic sectional view of a modification of the semiconductor device according to the embodiment of the present disclosure.

A semiconductor device 10C of a third modification illustrated in FIG. 15 is different from the semiconductor device 10B of the second modification only in the configuration of the filling portion 40. The configuration of the filling portion 40 that makes a difference from the semiconductor device 10B is described below, and description of configurations of the other portions is omitted.

As illustrated in FIG. 15, the filling portion 40 may include a magnetic material. The filling portion 40 illustrated in FIG. 15 includes a magnetic layer 45 in addition to the conductive layer 42.

The magnetic layer 45 includes a magnetic material. That is, in the filling portion 40 of the semiconductor device 10 of the third modification illustrated in FIG. 15, the magnetic layer 45 that is a part of the filling portion 40 includes a magnetic material, and the conductive layer 42 other than the above-mentioned part includes no conductive material.

The magnetic material is, for example, spherical metal magnetic powder. A major composition element of the metal magnetic powder is iron (Fe) and has a median diameter D50 of 5 μm or less. The metal magnetic powder is, for example, a composite material of metal with organic resin such as epoxy, phenol, acrylic, or polyimide. The metal magnetic powder is such a composite material as mentioned above, and thus insulation between powder particles is kept, making it possible to offer the semiconductor device 10 as a low-loss inductor component.

Each of the conductive layer 42 and the magnetic layer 45 penetrates the hole 20D along the thickness direction 101. In other words, each of the conductive layer 42 and the magnetic layer 45 extends from one end to the other end of the hole 20D along the thickness direction 101.

The magnetic layer 45 surrounds the conductive layer 42 as viewed along the thickness direction 101. In other words, the conductive layer 42 penetrates the magnetic layer 45 along the thickness direction 101. An outer surface of the magnetic layer 45 is in contact with the side surface 20Da of the hole 20D.

Alternatively, the conductive layer 42 is not necessarily required to penetrate the magnetic layer 45 along the thickness direction 101. For example, the conductive layer 42 may be provided on a side closer to the first capacitor portion 31 in the width direction 102 in the hole 20D, and the magnetic layer 45 may be provided on a side opposite to the first capacitor portion 31 in the width direction 102 in the hole 20D, so that the conductive layer 42 and the magnetic layer 45 may be provided side by side along the width direction 102 as viewed along the thickness direction 101.

The semiconductor device 10C is manufactured by a manufacturing method similar to the manufacturing method for the semiconductor device 10B. However, a filling material in the filling-portion forming step is different from that in the semiconductor device 10B. Specifically, firstly, the hole 20D is filled with the magnetic layer 45. Secondly, a hole drilled through the magnetic layer 45 along the thickness direction 101 is formed by a microdrill or a laser, and the hole is filled with the conductive layer 42.

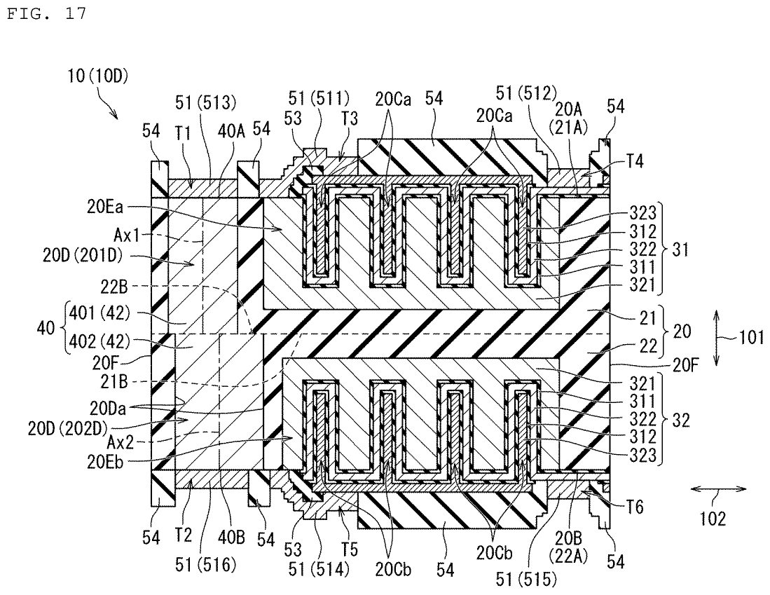

FIG. 16 is an equivalent circuit diagram of the semiconductor device illustrated in FIG. 15. The semiconductor device 10C is configured as described above, and thus forms a circuit as illustrated in FIG. 16. The circuit illustrated in FIG. 16 is substantially the same as the circuit illustrated in FIG. 3, but the filling portion 40 includes the magnetic layer 45, so that the resistor R illustrated in FIG. 3 is replaced with an inductor L.

According to the third modification, the magnetic layer 45 can function as a magnetic shield. Further, according to the third modification, the filling portion 40 can function as an inductor.

### Fourth Modification of Semiconductor Device

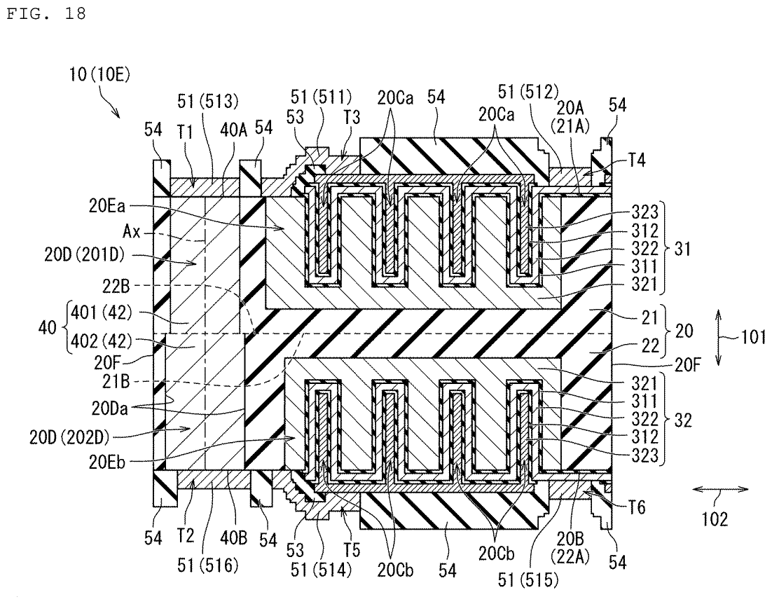

FIG. 17 is a schematic sectional view of a modification of the semiconductor device according to the embodiment of the present disclosure.

A semiconductor device 10D of a fourth modification illustrated in FIG. 17 is different from the semiconductor device 10 illustrated in FIG. 2 only in configurations of the hole 20D and the filling portion 40. The configurations of the hole 20D and the filling portion 40 that make a difference from the semiconductor device 10 are described below, and description of configurations of the other portions is omitted.

As illustrated in FIG. 17, the hole 20D includes a first hole 201D and a second hole 202D. The first hole 201D opens to the one main surface 20A. The second hole 202D opens to the other main surface 20B. The second hole 202D communicates with the first hole 201D.

The filling portion 40 includes the first filling portion 401 and the second filling portion 402. The first hole 201D is filled with the first filling portion 401. The second hole 202D is filled with the second filling portion 402. A centroid position Ax1 of the first filling portion 401 is different from a centroid position Ax2 of the second filling portion 402 as viewed along the thickness direction 101. Note that, in the present disclosure, the term “centroid position” means a geometric center in the first filling portion 401 or the second filling portion 402, where gravity of a mass is not taken into account.

Meanwhile, the hole 20D includes two portions (the first hole 201D and the second hole 202D) in FIG. 17, but may include three or more portions having different centroid positions. Further, the second hole 202D has an area larger than an area of the first hole 201D as viewed along the thickness direction 101 in FIG. 17, but the second hole 202D may have an area equal to or smaller than an area of the first hole 201D.

According to the fourth modification, a position of the filling portion 40 in the one main surface 20A and a position of the filling portion 40 in the other main surface 20B can be made different from each other, which improves the design flexibility of the semiconductor device 10D.

### Fifth Modification of Semiconductor Device

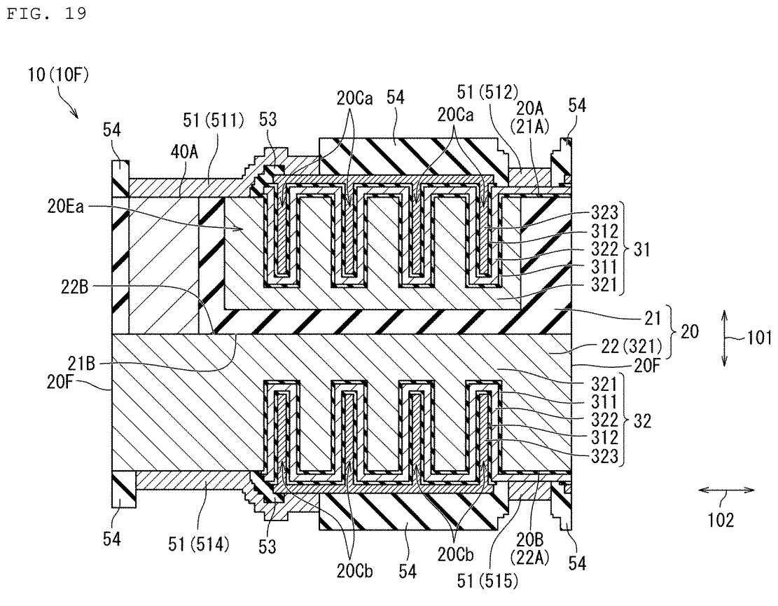

FIG. 18 is a schematic sectional view of a modification of the semiconductor device according to the embodiment of the present disclosure.

A semiconductor device 10E of a fifth modification illustrated in FIG. 18 is different from the semiconductor device 10D illustrated in FIG. 17 only in configurations of the hole 20D and the filling portion 40. The configurations of the hole 20D and the filling portion 40 that make a difference from the semiconductor device 10D are described below, and description of configurations of the other portions is omitted.

As illustrated in FIG. 18, the hole 20D of the semiconductor device 10E, like the hole 20D of the semiconductor device 10D, includes the first hole 201D and the second hole 202D.

The filling portion 40 of the semiconductor device 10E, like the filling portion 40 of the semiconductor device 10D, includes the first filling portion 401 and the second filling portion 402. In the semiconductor device 10E, the second hole 202D has an area larger than an area of the first hole 201D as viewed along the thickness direction 101. Further, in the semiconductor device 10E, a centroid position Ax of the first filling portion 401 is the same as a centroid position Ax of the second filling portion 402 as viewed along the thickness direction 101.

Note that the hole 20D includes two portions (the first hole 201D and the second hole 202D) in FIG. 18, but may include three or more portions having the same centroid position and having different areas as viewed along the thickness direction 101. Further, the second hole 202D has an area larger than an area of the first hole 201D as viewed along the thickness direction 101 in FIG. 18, but the second hole 202D may have an area smaller than an area of the first hole 201D.

According to the fifth modification, the size of the filling portion 40 in the one main surface 20A and the size of the filling portion 40 in the other main surface 20B are different from each other, which improves the design flexibility of the semiconductor device 10D.

### Sixth Modification of Semiconductor Device

FIG. 19 is a schematic sectional view of a modification of the semiconductor device according to the embodiment of the present disclosure.

As illustrated in FIG. 19, the semiconductor substrate 20 of a semiconductor device 10F includes the first substrate 21 and the second substrate 22. The first substrate 21, like the semiconductor substrate 20 illustrated in FIG. 2, includes high-resistance Si having an insulation property. The second substrate 22 includes the first electrode layer 321. The first substrate 21 and the second substrate 22 are bonded by a known process such as thermocompression bonding.

In the semiconductor device 10F, the hole 20D is drilled through the first substrate 21 along the thickness direction 101. Meanwhile, the second substrate 22 (the first electrode layer 321) does not include the hole 20D. That is, in the semiconductor device 10F, the hole 20D is not drilled through the semiconductor substrate 20 and is bottomed. The hole 20D opens to the one main surface 20A and is bottomed on a side closer to the other main surface 20B.

The hole 20D is filled with the filling portion 40. A bottom surface of the hole 20D includes the second substrate 22. That is, the bottom surface of the hole 20D includes the first electrode layer 321 included in the second capacitor portion 32. Hence, a portion forming the bottom surface of the hole 20D in the first electrode layer 321 is in contact with the filling portion 40. That is, the first electrode layer 321 and the filling portion 40 are electrically connected to each other.

According to the sixth modification, there is no need to configure the hole 20D so as to be drilled through the semiconductor substrate 20 along the thickness direction 101. This enables reduction in the depth of the hole 20D. Further, whereas the hole 20D drilled through one of two substrates is provided in manufacture of the semiconductor device 10F by bonding of the two substrates (the first substrate 21 and the second substrate 22), there is no need to provide the hole 20D in the other of the two substrates. As a result, a configuration in which the one main surface 20A and the other main surface 20B are electrically connected can be realized at a lower cost, as compared with a configuration in which the hole 20D is drilled through the semiconductor substrate 20 along the thickness direction 101.

### Module Unit

FIG. 20 is a schematic sectional view of a module unit according to the embodiment of the present disclosure.

As illustrated in FIG. 20, the module unit 70 includes the semiconductor device 10 described in the above-described embodiment and each modification, an electronic component 71, and a mounting board 72 serving as an interposer layer in which the semiconductor device 10 and the electronic component 71 are provided. Each of the electronic component 71 and the mounting board 72 in FIG. 20 has an area larger than an area of the semiconductor device 10 as viewed along the thickness direction 101, but may have an area equal to or smaller than an area of the semiconductor device 10.

The electronic component 71 is mounted on at least one of a front mounting surface 72A or a rear mounting surface 72B of the mounting board 72. In the configuration illustrated in FIG. 20, the electronic component 71 is mounted on the front mounting surface 72A. In the configuration illustrated in FIG. 20, the front mounting surface 72A corresponds to a mounting surface. The electronic component 71 is an integrated circuit (IC), but is not limited to an IC. For example, the electronic component 71 may be a resistor, an inductor, or the like.

The mounting board 72 illustrated in FIG. 20 includes a core part 721 that is a resin molding material including inorganic filler, and insulating substrates 722 and 723 provided so as to have the core part 721 sandwiched therebetween along the thickness direction 101.

The semiconductor device 10 is provided in the mounting board 72. In the configuration illustrated in FIG. 20, the semiconductor device 10 is provided in the core part 721. The semiconductor device 10 illustrated in FIG. 20 includes the four filling portions 40, but the number of the filling portions 40 is not limited to four. Note that the semiconductor device 10 may be mounted on at least one of the front mounting surface 72A or the rear mounting surface 72B of the mounting board 72. The semiconductor device 10 is not limited to one having the configuration illustrated in FIG. 20, and may have various configurations described above.

An internal electrode 724 is provided in the insulating substrates 722 and 723. An external electrode 725 is provided in the front mounting surface 72A and the rear mounting surface 72B. That is, the insulating substrates 722 and 723, the internal electrode 724, and the external electrode 725 form a redistribution layer (RDL).

A through electrode 726 can penetrate at least one of the core part 721, the insulating substrate 722, or the insulating substrate 723. The through electrode 726 can be electrically connected to the internal electrode 724 and the external electrode 725.

In the mounting board 72 illustrated in FIG. 20, at least a part of the semiconductor device 10 and at least a part of the electronic component 71 overlap each other as viewed along the thickness direction 101.

The core part 721 includes, for example, epoxy or silica. The insulating substrates 722 and 723 include, for example, silicon.

Note that the mounting board 72 is not limited to the configuration including the core part 721 and the insulating substrates 722 and 723 as illustrated in FIG. 20. For example, the mounting board 72 may include a glass core. In this case, the mounting board 72 includes glass fibers. Including glass fibers increases the strength of the mounting board 72, thereby suppressing warp of the board.

According to the present embodiment, the semiconductor device 10 can be provided in the vicinity of the electronic component 71. This results in improvement of the signal integrity (SI) of the semiconductor device 10.

The semiconductor devices and the module unit described above can also be expressed as follows.

According to a first aspect of the present disclosure, there is provided a semiconductor device including a semiconductor substrate including one main surface and the other main surface that is provided while being spaced away from the one main surface along a thickness direction and faces in a direction opposite to the one main surface along the thickness direction, the semiconductor substrate including at least one first trench in the one main surface and at least one second trench in the other main surface; a first capacitor portion that is provided at least in the first trench and includes a dielectric layer and two electrode layers between which the dielectric layer is sandwiched; and a second capacitor portion that is provided at least in the second trench and includes a dielectric layer and two electrode layers between which the dielectric layer is sandwiched.

According to a second aspect of the present disclosure, there is provided the semiconductor device according to the first aspect, wherein the semiconductor substrate further includes a hole that extends along the thickness direction, opens to at least one of the one main surface or the other main surface, and has an area larger than that of each of the first trench and the second trench as viewed along the thickness direction, the semiconductor device further including a filling portion that is provided in the hole and includes a conductive material.

According to a third aspect of the present disclosure, there is provided the semiconductor device according to the second aspect, wherein the hole opens to both the one main surface and the other main surface.

According to a fourth aspect of the present disclosure, there is provided the semiconductor device according to the second aspect or the third aspect, wherein the filling portion includes a buried layer including resin; a conductive layer that surrounds the buried layer as viewed along the thickness direction and includes a conductive material; a barrier layer that surrounds the conductive layer as viewed along the thickness direction and includes a conductive material; and an isolation layer that surrounds the barrier layer as viewed along the thickness direction and includes an insulating material.

According to a fifth aspect of the present disclosure, there is provided the semiconductor device according to any one of the second to fourth aspects, wherein the filling portion is electrically connected to both the first capacitor portion and the second capacitor portion.

According to a sixth aspect of the present disclosure, there is provided the semiconductor device according to any one of the second to fifth aspects, wherein the filling portion includes a conductive layer that extends from one end to the other end of the hole along the thickness direction and includes a conductive material; and a magnetic layer that extends from the one end to the other end of the hole along the thickness direction and includes a magnetic material.

According to a seventh aspect of the present disclosure, there is provided the semiconductor device according to the sixth aspect, wherein the conductive layer penetrates the magnetic layer along the thickness direction.

According to an eighth aspect of the present disclosure, there is provided the semiconductor device according to any one of the second to seventh aspects, wherein the hole includes a first hole opening to the one main surface, and a second hole that opens to the other main surface and communicates with the first hole, the filling portion includes a first filling portion with which the first hole is filled, and a second filling portion with which the second hole is filled, and a centroid position of the first filling portion is different from a centroid position of the second filling portion as viewed along the thickness direction.

According to a ninth aspect of the present disclosure, there is provided the semiconductor device according to any one of the second to eighth aspects, wherein the hole includes a first hole opening to the one main surface, and a second hole that opens to the other main surface and communicates with the first hole, and the first hole has an area different from an area of the second hole as viewed along the thickness direction.

According to a tenth aspect of the present disclosure, there is provided the semiconductor device according to any one of the second to ninth aspects, wherein the hole opens to the one main surface and is bottomed on a side closer to the other main surface, a bottom surface of the hole includes the electrode layer included in the second capacitor portion, and the filling portion with which the hole is filled is in contact with a portion forming the bottom surface in the electrode layer included in the second capacitor portion.

According to an eleventh aspect of the present disclosure, there is provided the semiconductor device according to any one of the first to tenth aspects, further including conductive external terminals provided in both the one main surface and the other main surface.

According to a twelfth aspect of the present disclosure, there is provided the semiconductor device according to the eleventh aspect, wherein a specific external terminal that is at least one of the external terminals protrudes along the thickness direction with respect to a specific main surface that is the one main surface or the other main surface in which the specific external terminal is provided, and a protrusion length of the specific external terminal with respect to the specific main surface along the thickness direction is larger than a protrusion length of another portion provided in the specific main surface other than the specific external terminal, with respect to the specific main surface along the thickness direction.

According to a thirteenth aspect of the present disclosure, there is provided the semiconductor device according to any one of the first to twelfth aspects, wherein at least a part of the first capacitor portion and at least a part of the second capacitor portion are located so as to overlap each other as viewed along the thickness direction.

According to a fourteenth aspect of the present disclosure, there is provided the semiconductor device according to any one of the first to thirteenth aspects, wherein an electrode layer that is provided outside the first trench and forms at least a part of the semiconductor substrate, out of the two electrode layers included in the first capacitor portion, is integral with an electrode layer that is provided outside the second trench and forms at least a part of the semiconductor substrate, out of the two electrode layers included in the second capacitor portion.

According to a fifteenth aspect of the present disclosure, there is provided the semiconductor device according to any one of the first to fourteenth aspects, further including an insulating protective film covering at least one of the one main surface or the other main surface.

According to a sixteenth aspect of the present disclosure, there is provided the semiconductor device according to any one of the first to fifteenth aspects, further including a first wiring layer that is located on the one main surface and has conductivity; and a second wiring layer that is located on the other main surface, includes a material different from a material of the first wiring layer, and has conductivity.

According to a seventeenth aspect of the present disclosure, there is provided the semiconductor device according to any one of the first to sixteenth aspects, wherein at least one of a number or a size of the first trench is different from at least one of a number or a size of the second trench, and capacitance of the first capacitor portion is different from capacitance of the second capacitor portion.

According to an eighteenth aspect of the present disclosure, there is provided the semiconductor device according to any one of the first to seventeenth aspects, wherein the semiconductor substrate includes a first substrate including the first trench; a second substrate including the second trench; and an adhesive layer that is located between the first substrate and the second substrate and adhesively bonds the first substrate and the second substrate.

According to a nineteenth aspect of the present disclosure, there is provided a module unit including the semiconductor device according to any one of the first to eighteenth aspects; an electronic component; and a mounting board in which the semiconductor device is provided, the mounting board including a mounting surface on which the electronic component is mounted.

According to a twentieth aspect of the present disclosure, there is provided a method for manufacturing a semiconductor device, including a first-trench forming step of forming at least one first trench in a main surface of a first substrate; a first-capacitor-portion forming step of forming a first capacitor portion including a dielectric layer and two electrode layers between which the dielectric layer is sandwiched, in at least the first trench in the first substrate; a second-trench forming step of forming at least one second trench in a main surface of a second substrate; a second-capacitor-portion forming step of forming a second capacitor portion including a dielectric layer and two electrode layers between which the dielectric layer is sandwiched, in at least the second trench in the second substrate; and a bonding step of bonding a rear surface with respect to the main surface of the first substrate and a rear surface with respect to the main surface of the second substrate.

Note that appropriately combining any of the various embodiments described above could produce the respective effects of the various embodiments. For example, in the semiconductor device 10A illustrated in FIG. 12, the respective trenches have different sizes, and such a configuration in which the respective trenches have different sizes may be applied to the semiconductor device 10 according to another embodiment or modification.

While the present disclosure has been fully described in connection with preferred embodiments with reference to the accompanying drawings as appropriate, various alterations and revisions are obvious to those skilled in the art. Such alterations and revisions should be understood as being within the scope of the present disclosure recited by the appended claims unless they depart therefrom.

What is claimed is:

1. A semiconductor device comprising:
a semiconductor substrate including one main surface and an other main surface that is spaced away from the one main surface along a thickness direction and faces in a direction opposite to the one main surface along the thickness direction, the semiconductor substrate including at least one first trench in the one main surface and at least one second trench in the other main surface;
a first capacitor portion that is at least in the first trench and includes a dielectric layer and two electrode layers between which the dielectric layer is sandwiched; and
a second capacitor portion that is at least in the second trench and includes a dielectric layer and two electrode layers between which the dielectric layer is sandwiched.

2. The semiconductor device according to claim 1, wherein
the semiconductor substrate further includes a hole that extends along the thickness direction, opens to at least one of the one main surface or the other main surface, and has an area larger than that of each of the first trench and the second trench as viewed along the thickness direction,
the semiconductor device further comprising a filling portion that is in the hole and includes a conductive material.

3. The semiconductor device according to claim 2, wherein
the hole opens to both the one main surface and the other main surface.

4. The semiconductor device according to claim 2, wherein
the filling portion includes:
a buried layer including resin;
a conductive layer that surrounds the buried layer as viewed along the thickness direction and includes a conductive material;
a barrier layer that surrounds the conductive layer as viewed along the thickness direction and includes a conductive material; and
an isolation layer that surrounds the barrier layer as viewed along the thickness direction and includes an insulating material.

5. The semiconductor device according to claim 2, wherein
the filling portion is electrically connected to both the first capacitor portion and the second capacitor portion.

6. The semiconductor device according to claim 2, wherein
the filling portion includes:
a conductive layer that extends from one end to an other end of the hole along the thickness direction and includes a conductive material; and
a magnetic layer that extends from the one end to the other end of the hole along the thickness direction and includes a magnetic material.

7. The semiconductor device according to claim 6, wherein
the conductive layer penetrates the magnetic layer along the thickness direction.

8. The semiconductor device according to claim 2, wherein
the hole includes:
a first hole opening to the one main surface; and
a second hole that opens to the other main surface and communicates with the first hole,
the filling portion includes:
a first filling portion with which the first hole is filled; and
a second filling portion with which the second hole is filled, and
a centroid position of the first filling portion is different from a centroid position of the second filling portion as viewed along the thickness direction.

9. The semiconductor device according to claim 2, wherein
the hole includes:
a first hole opening to the one main surface; and
a second hole that opens to the other main surface and communicates with the first hole, and
the first hole has an area different from an area of the second hole as viewed along the thickness direction.

10. The semiconductor device according to claim 2, wherein
the hole opens to the one main surface and is bottomed on a side closer to the other main surface, and
a bottom surface of the hole includes the electrode layer included in the second capacitor portion, and
the filling portion with which the hole is filled is in contact with a portion defining the bottom surface in the electrode layer included in the second capacitor portion.

11. The semiconductor device according to claim 1, further comprising:
conductive external terminals in both the one main surface and the other main surface.

12. The semiconductor device according to claim 11, wherein
a specific external terminal that is at least one of the external terminals protrudes along the thickness direction with respect to a specific main surface that is the one main surface or the other main surface in which the specific external terminal is present, and
a protrusion length of the specific external terminal with respect to the specific main surface along the thickness direction is larger than a protrusion length of another portion in the specific main surface other than the specific external terminal, with respect to the specific main surface along the thickness direction.

13. The semiconductor device according to claim 1, wherein
at least a part of the first capacitor portion and at least a part of the second capacitor portion overlap each other as viewed along the thickness direction.

14. The semiconductor device according to claim 1, wherein
an electrode layer that is outside the first trench and defines at least a part of the semiconductor substrate, out of the two electrode layers included in the first capacitor portion is integral with an electrode layer that is outside the second trench and defines at least a part of the semiconductor substrate, out of the two electrode layers included in the second capacitor portion.

15. The semiconductor device according to claim 1, further comprising:
an insulating protective film covering at least one of the one main surface or the other main surface.

16. The semiconductor device according to claim 1, further comprising:
a first wiring layer that is on the one main surface and has conductivity; and
a second wiring layer that is on the other main surface, includes a material different from a material of the first wiring layer, and has conductivity.

17. The semiconductor device according to claim 1, wherein
at least one of a number or a size of the first trench is different from at least one of a number or a size of the second trench, and
capacitance of the first capacitor portion is different from capacitance of the second capacitor portion.

18. The semiconductor device according to claim 1, wherein
the semiconductor substrate includes:
a first substrate including the first trench;
a second substrate including the second trench; and
an adhesive layer that is between the first substrate and the second substrate and adhesively bonds the first substrate and the second substrate.

19. A module unit comprising:
the semiconductor device according to claim 1;
an electronic component; and
a mounting board in which the semiconductor device is present, the mounting board including a mounting surface on which the electronic component is mounted.

20. A method for manufacturing a semiconductor device, comprising:
forming at least one first trench in a main surface of a first substrate;
forming a first capacitor portion including a dielectric layer and two electrode layers between which the dielectric layer is sandwiched, in at least the first trench in the first substrate;
forming at least one second trench in a main surface of a second substrate;
forming a second capacitor portion including a dielectric layer and two electrode layers between which the dielectric layer is sandwiched, in at least the second trench in the second substrate; and
bonding a rear surface with respect to the main surface of the first substrate and a rear surface with respect to the main surface of the second substrate.
